(19) United States
(12) Patent Application Publication
(10) Pub. No.: US 2007/0215950 A1
(43) Pub. Date: Sep. 20, 2007

(54) Semiconductor device and manufacturing method thereof

(76) Inventor: Tomonori Aoyama, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/723,226

(22) Filed: Mar. 19, 2007

(30) Foreign Application Priority Data
Mar. 20, 2006 (JP) 2006-077525

(51) Int. Cl. H01L 29/94

(52) U.S. Cl. 257/369

(57) ABSTRACT

A manufacturing method of a semiconductor device according to an embodiment of this invention, includes: forming a gate dielectric film on a substrate and forming a gate electrode layer for a P-type FET on the gate dielectric film, ranging from a P-type FET region to a N-type FET region; in the P-type FET region and the N-type FET region, processing the gate electrode layer for the P-type FET, to form a gate electrode for the P-type FET in the P-type FET region, and to form a dummy gate electrode in the N-type FET region; and in the N-type FET region, forming a trench by removing the dummy gate electrode on the gate dielectric film, and forming a gate electrode for the N-type FET on the gate dielectric film by burying a gate electrode material in the trench.

### CROSS REFERENCE TO RELATED APPLICATIONS

This application is based upon and claims the benefit of priority from the prior Japanese Patent Application No. 2006-77525, filed on Mar. 20, 2006, the entire contents of which are incorporated herein by reference.

### BACKGROUND OF THE INVENTION

1. Field of the Invention

The present invention relates to a semiconductor device and a manufacturing method thereof, for example, to a semiconductor device which includes a PMOSFET and an NMOSFET which are constituted by high-permittivity gate dielectric films (high-k gate dielectric films) and metal gate electrodes, and a manufacturing method thereof.

2. Related Art

The currently most widely used transistors are FETs (Field Effect Transistors) such as MOSFETs. Among them, a CMOSFET (Complementary MOSFET) constituted by a PMOSFET (P-channel MOSFET) and an NMOSFET (N-channel MOSFET) is particularly widely used.

A silicon oxide film or silicon oxynitride film is widely adopted as a gate dielectric film in a conventional FET. Although demand for thinner gate dielectric films has recently been increasing along with miniaturization of integrated circuits, there is a limit of thinning a silicon oxide film or silicon oxynitride film due to an increase in leakage current. For example, a CMOSFET for the 45 nm technology node or beyond requires performance, equivalent to that of a gate dielectric film with an equivalent oxide thickness of 1.3 nm or less. However, it is difficult to achieve such performance by thinning a silicon oxide film or silicon oxynitride film. For this reason, there has been proposed a method, thinning a gate dielectric film while suppressing an increase in leakage current, by adopting, as the gate dielectric film, a metal dielectric film with a higher permittivity than a silicon oxide film or silicon oxynitride film (high-permittivity gate dielectric film). Examples of the metal dielectric film include a metal oxide film, metal oxynitride film, metal silicate film, metal silicon oxynitride film, and the like.

Polysilicon is widely adopted as a material for forming a gate electrode in a conventional FET. When polysilicon is adopted as a material for forming gate electrodes of a CMOSFET, implantation of ions of boron or boron fluoride into the gate electrode of a PMOSFET, implantation of ions of phosphorus or arsenic into the gate electrode of an NMOSFET, and annealing at 1,000° C. or more for activation of these impurities, are usually performed.

A CMOSFET which adopts a high-permittivity gate dielectric film as a gate dielectric film and polysilicon as a material for forming a gate electrode can be formed by a forming method similar to a conventional one. In such a CMOSFET, the threshold voltage of an NMOSFET has a relatively proper value while that of a PMOSFET significantly shifts to the negative side. Additionally, the inversion capacitance of the PMOSFET becomes lower than that of the NMOSFET. If the threshold voltage of the PMOSFET significantly shifts to the negative side, and the inversion capacitance of the PMOSFET becomes low, a desired drain current cannot be ensured in the PMOSFET (T. Aoyama et al., Proc. IWGI 174 (2003)).

For this reason, there has been proposed a method, suppressing a shift in the threshold voltage of a PMOSFET and increasing the inversion capacitance of the PMOSFET, by adopting a metal gate electrode as a gate electrode of a CMOSFET when a high-permittivity gate dielectric film is adopted as a gate dielectric film of the CMOSFET. The term “metal” in metal gate electrode refers to a simple substance metal, an alloy, and a compound including such a metal or alloy (e.g., a silicide, siliconitride, nitride, carbide, or carbonitride). If a metal gate electrode is adopted as the gate electrode of a PMOSFET, the following things can be ensured. Firstly, since the threshold voltage changes according to the work function of the metal used, an appropriate threshold voltage can be ensured by using a metal with an appropriate work function. Secondly, since depletion is less likely to occur in a metal than in polysilicon, a sufficient inversion capacitance can be ensured.

A metal suitable for the metal gate electrode of a PMOSFET is a metal with a work function of 4.8 eV or more, and a metal suitable for the metal gate electrode of an NMOSFET is a metal with a work function of 4.3 eV or less. Adoption of such metals for the metal gate electrodes of a PMOSFET and an NMOSFET is preferable in terms of the design of a CMOSFET, because the work functions of the gate electrodes of the PMOSFET and the NMOSFET become same to those of conventional PMOSFET and NMOSFET. When a PMOSFET was subjected to a heat resistance test using metals such as W, Ru, and Pt with a work function of 4.8 eV or more, it turned out that it was possible to keep the work function at 4.8 eV or more even after annealing at 1,000 to 1,030° C. However, when an NMOSFET was subjected to a heat resistance test using metals such as TaSi, TaSiN, TaC, TaCN, TaSiCN, HfN, HfSi, HfSiN, WSi, TaHf, and TaHfN with a work function of 4.3 eV or less, it turned out that spike annealing at about 1,000° C. changed the work function to about 4.5 eV, and that it was impossible to keep the work function at 4.3 eV or less. Furthermore, it was impossible to measure the work function after the annealing with regard to some of the metals, so it was supposed that a reaction occurred in some of the metals. Accordingly, if a high-permittivity gate dielectric film and a metal gate electrode are adopted in a CMOSFET, it is difficult to form the CMOSFET by a forming method similar to a conventional one. This is because the work function of the metal gate electrode of an NMOSFET changes in the step of forming a source/drain diffusion layer requiring annealing at about 1,000° C.

Therefore, there is proposed a method, forming, when a high-permittivity gate dielectric film and a metal gate electrode are adopted in a CMOSFET, a dummy gate dielectric film made of a silicon oxide film and a dummy gate electrode made of polysilicon, removing the dummy gate dielectric film and dummy gate electrode after forming a source/drain diffusion layer, and forming a real high-permittivity gate dielectric film and metal gate electrode; the method is called the “damascene gate process” (A. Chatterjee et al., IEDM Tech. Dig. 821 (1997) and A. Yagishita et al., IEDM Tech. Dig. 785 (1998)). Since, in this method, a metal gate electrode is formed after a source/drain diffusion layer is formed, the work function of the metal gate electrode of an NMOSFET does not change in the step of forming the source/drain diffusion layer requiring annealing at about 1,000° C.

In the damascene gate process, the dummy gate dielectric film is damaged in removing the dummy gate electrode, so it is necessary to remove also the dummy gate dielectric film in removing the dummy gate electrode. Therefore, in the damascene gate process, the dummy gate electrode and dummy dielectric film are removed, and the high-permittivity gate dielectric film is formed. However, the high-permittivity gate dielectric film is formed not only on a channel but also on a side wall, so an overlap capacitance (Cov) becomes high and the roll-off characteristics of the threshold value are degraded. Additionally, in the damascene gate process, a leakage current in the high-permittivity gate dielectric film is suppressed by nitridation and annealing performed for removal of residual impurities and compensation of oxygen deficiency. However, there is a constraint on the damascene gate process, in which the high-permittivity gate dielectric film is formed after the source/drain layer is formed, that the step of forming the high-permittivity gate dielectric film should be performed at 500° C. or less, to prevent agglomeration of NiSi on the surface of the source/drain diffusion layer, and to suppress diffusion of impurities in the source/drain diffusion layer. Such a constraint makes it difficult to improve the quality of the high-permittivity gate dielectric film to suppress a leakage current in it.

### SUMMARY OF THE INVENTION

An embodiment of the present invention is, for example, a manufacturing method of a semiconductor device, for forming a P-type FET and an N-type FET in a P-type FET region and an N-type FET region of a substrate respectively, the method including:

forming a gate dielectric film common to the P-type FET and the N-type FET, ranging from the P-type FET region to the N-type FET region, on the substrate,

forming a gate electrode layer for the P-type FET, ranging from the P-type FET region to the N-type FET region, on the gate dielectric film,

processing, in the P-type FET region and the N-type FET region, the gate electrode layer for the P-type FET, to form a gate electrode for the P-type FET in the P-type FET region, and to form a dummy gate electrode in the N-type FET region,

forming, in the P-type FET region and the N-type FET region, a source/drain diffusion layer for the P-type FET and a source/drain diffusion layer for the N-type FET in the substrate, after the gate electrode for the P-type FET and the dummy gate electrode are formed,

forming, in the N-type FET region, a trench on the gate dielectric film, by removing the dummy gate electrode on the gate dielectric film, and

forming, in the N-type FET region, a gate electrode for the N-type FET on the gate dielectric film, by burying a gate electrode material in the trench on the gate dielectric film.

Another embodiment of the present invention is, for example, a semiconductor device including:

a substrate,

a gate dielectric film for a P-type FET and a gate dielectric film for an N-type FET, formed on the substrate and formed from a gate dielectric film common to the P-type FET and the N-type FET,

a gate electrode for the P-type FET, formed on the gate dielectric film for the P-type FET and having no seam in the gate electrode, and

a gate electrode for the N-type FET, formed on the gate dielectric film for the N-type FET and having a seam in the gate electrode.

Another embodiment of the present invention is, for example, a semiconductor device manufactured by forming a P-type FET and an N-type FET in a P-type FET region and an N-type FET region of a substrate respectively, the device being manufactured by:

forming a gate dielectric film common to the P-type FET and the N-type FET, ranging from the P-type FET region to the N-type FET region, on the substrate,

forming a gate electrode layer for the P-type FET, ranging from the P-type FET region to the N-type FET region, on the gate dielectric film,

processing, in the P-type FET region and the N-type FET region, the gate electrode layer for the P-type FET, to form a gate electrode for the P-type FET in the P-type FET region, and to form a dummy gate electrode in the N-type FET region,

forming, in the P-type FET region and the N-type FET region, a source/drain diffusion layer for the P-type FET and a source/drain diffusion layer for the N-type FET in the substrate, after the gate electrode for the P-type FET and the dummy gate electrode are formed,

forming, in the N-type FET region, a trench on the gate dielectric film, by removing the dummy gate electrode on the gate dielectric film, and

forming, in the N-type FET region, a gate electrode for the N-type FET on the gate dielectric film, by burying a gate electrode material in the trench on the gate dielectric film.

### BRIEF DESCRIPTION OF THE DRAWINGS

FIG. 1 is a side sectional view showing a semiconductor device according to a first embodiment;

FIGS. 2A to 2N are side sectional views (1-14) showing a method for manufacturing the semiconductor device of the first embodiment;

FIG. 3 is a side sectional view showing a semiconductor device according to a second embodiment;

FIGS. 4A to 4N are side sectional views (1-14) showing a method for manufacturing the semiconductor device of the second embodiment;

FIG. 5 is a side sectional view showing a semiconductor device according to a third embodiment; and

FIGS. 6A to 6Q are side sectional views (1-17) showing a method for manufacturing the semiconductor device of the third embodiment.

### DETAILED DESCRIPTION OF THE INVENTION

### First Embodiment

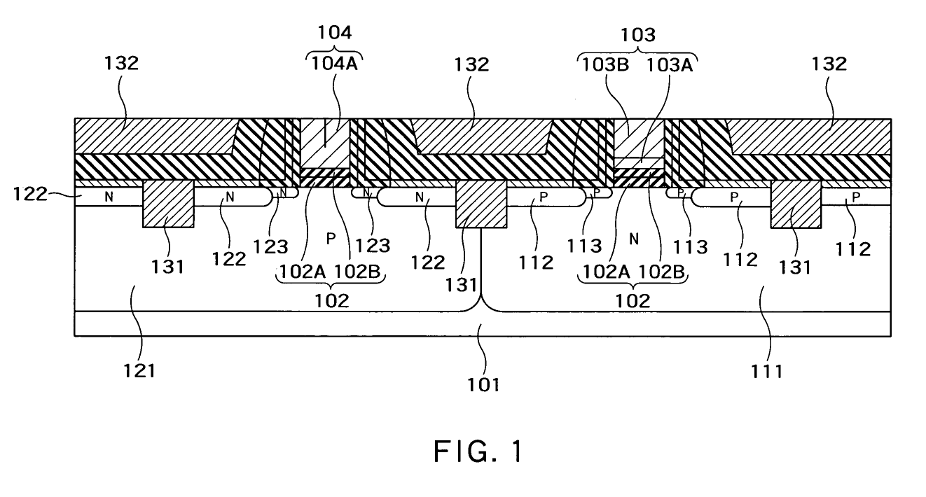

FIG. 1 is a side sectional view showing a semiconductor device according to a first embodiment. The semiconductor device in FIG. 1 includes a PMOSFET which is a specific example of a P-type FET and an NMOSFET which is a specific example of an N-type FET. The semiconductor device in FIG. 1 includes a CMOSFET which is constituted by the PMOSFET and the NMOSFET.

The semiconductor device shown in FIG. 1 includes a substrate 101, gate dielectric films 102, a gate electrode 103 for the PMOSFET, and a gate electrode 104 for the NMOSFET. The substrate 101 is a semiconductor substrate, all or a part of which is made of a semiconductor. The substrate 101 in this embodiment is a silicon substrate, all or a part of which is made of silicon. Each gate dielectric film 102 is a high-permittivity gate dielectric film, all or a part of which is made of a high-permittivity dielectric film. Each gate dielectric film 102 in this embodiment includes two layers of dielectric films: a first dielectric film 102A which is a silicon oxide film and a second dielectric film 102B which is a high-permittivity dielectric film. The gate electrode 103 for the PMOSFET is a metal gate electrode, all or a part of which is made of conductive metal. The gate electrode 103 for the PMOSFET in this embodiment includes two electrode-constituting layers: a first conductive layer 103A which is made of conductive metal and a second conductive layer 103B which is made of conductive metal. The gate electrode 104 for the NMOSFET is a metal gate electrode, all or a part of which is made of conductive metal. The gate electrode 104 for the NMOSFET in this embodiment includes one electrode-constituting layer: a third conductive layer 104A which is made of conductive metal.

Additionally, the semiconductor device shown in FIG. 1 has, as diffusion layers for the PMOSFET, a well diffusion layer 111 for the PMOSFET, a source/drain diffusion layer 112 for the PMOSFET, and an extension diffusion layer 113 for the PMOSFET. The well diffusion layer 111 is an N-type diffusion layer, the source/drain diffusion layer 112 is a P-type diffusion layer, and the extension diffusion layer 113 is a P-type diffusion layer.

Additionally, the semiconductor device shown in FIG. 1 has, as diffusion layers for the NMOSFET, a well diffusion layer 121 for the NMOSFET, a source/drain diffusion layer 122 for the NMOSFET, and an extension diffusion layer 123 for the NMOSFET. The well diffusion layer 121 is a P-type diffusion layer, the source/drain diffusion layer 122 is an N-type diffusion layer, and the extension diffusion layer 123 is an N-type diffusion layer.

Additionally, the semiconductor device shown in FIG. 1 has an isolation layer 131 for intervening between the source/drain diffusion layer 112 for the PMOSFET and the source/drain diffusion layer 122 for the NMOSFET, and an inter layer dielectric film 132 for intervening between the PMOSFET and the NMOSFET. The isolation layer 131 in this embodiment is an STI layer which is made of a silicon oxide film, and the inter layer dielectric film 132 in this embodiment is a silicon oxide film.

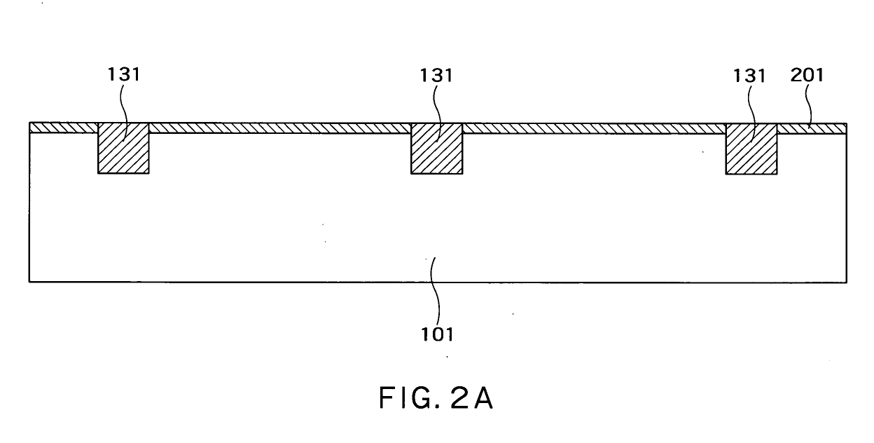

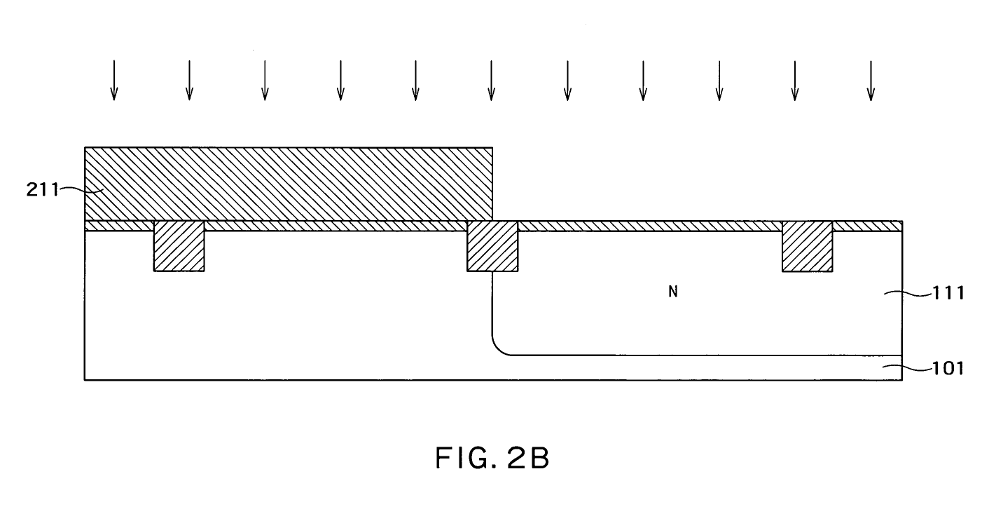

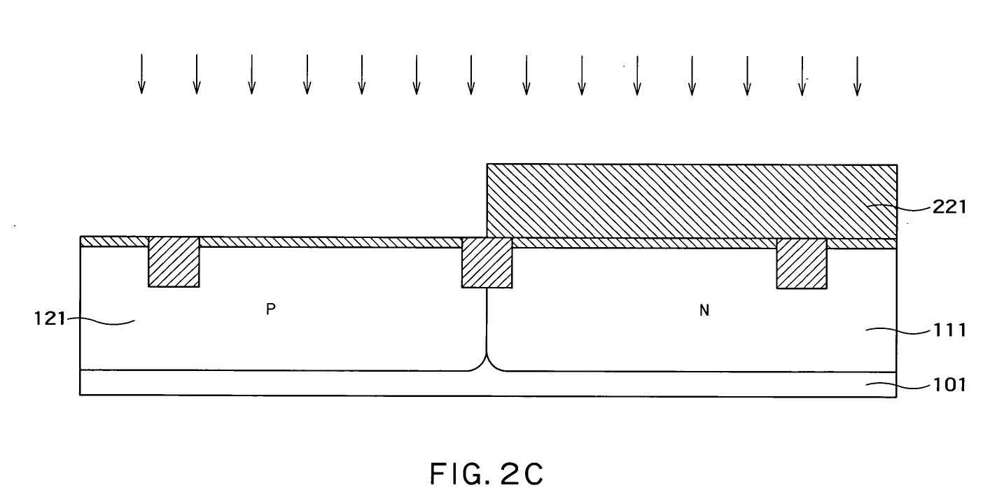

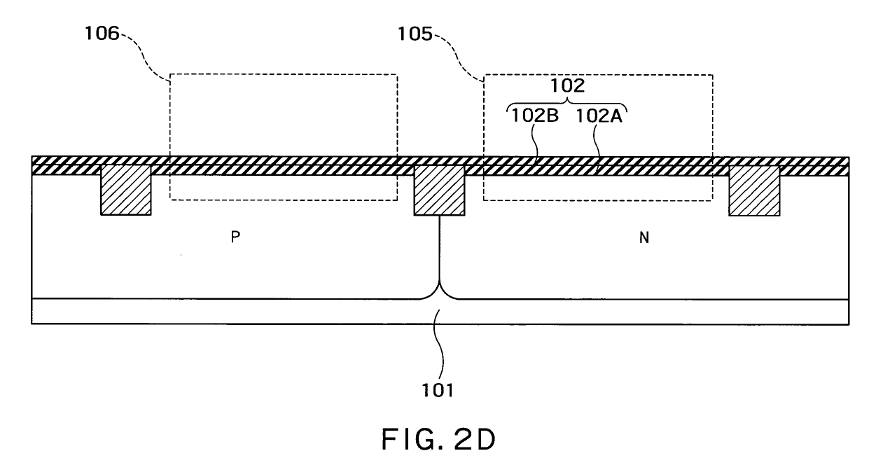

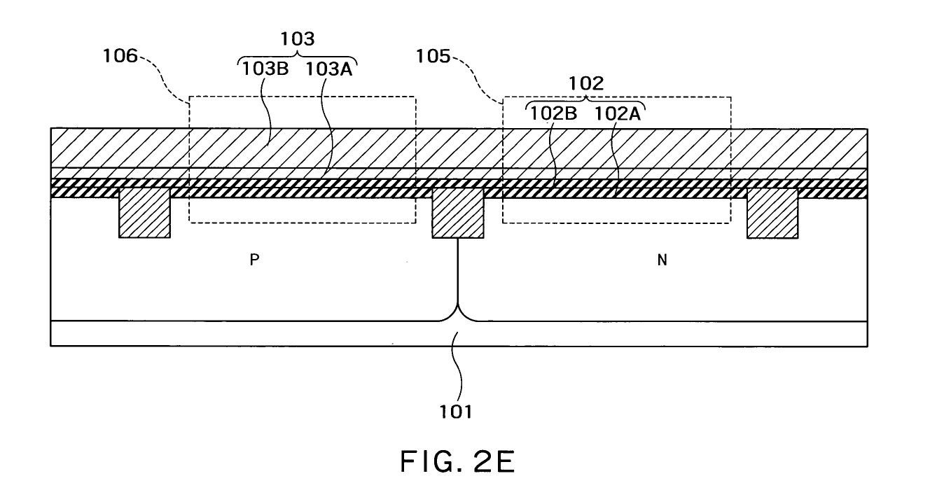

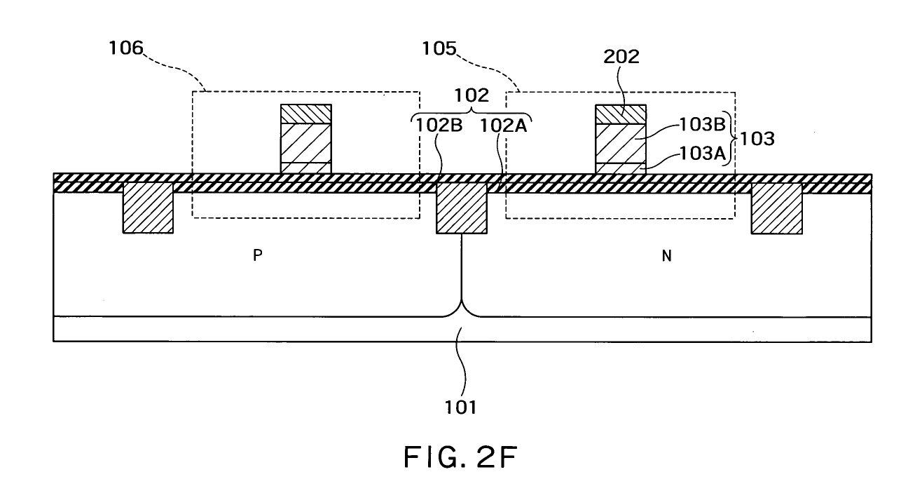

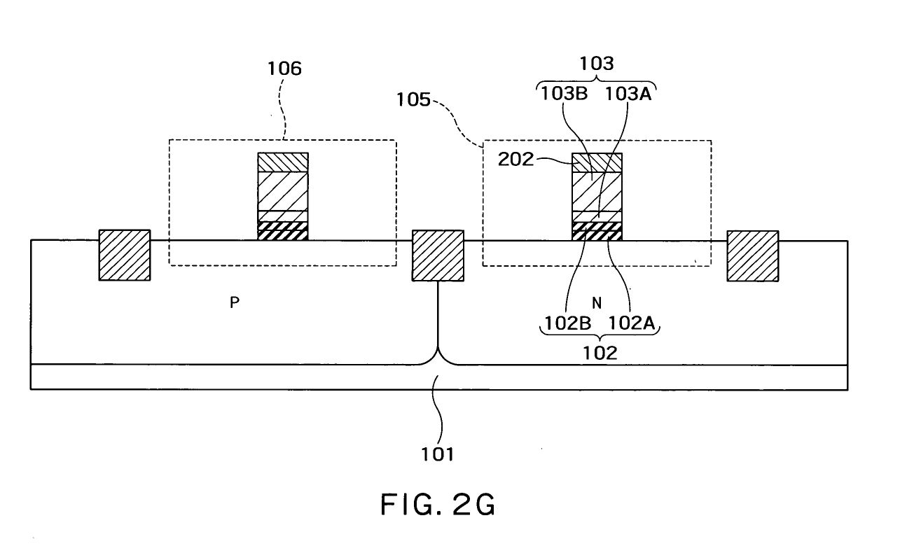

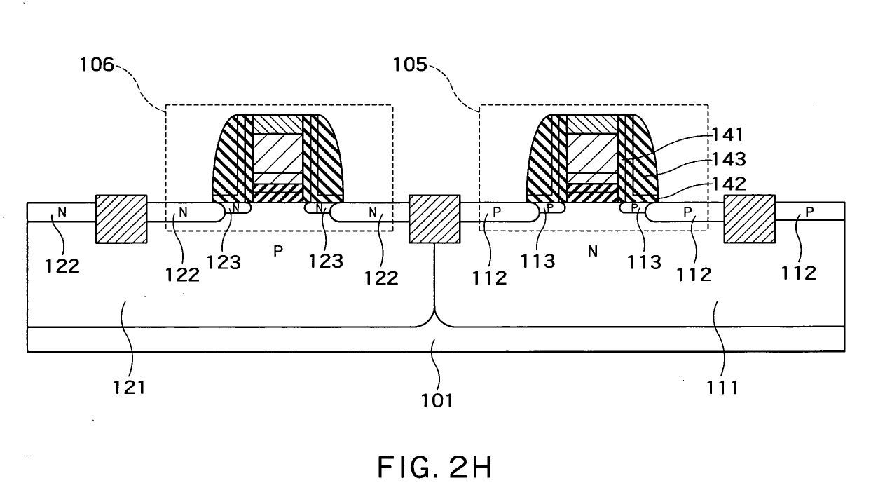

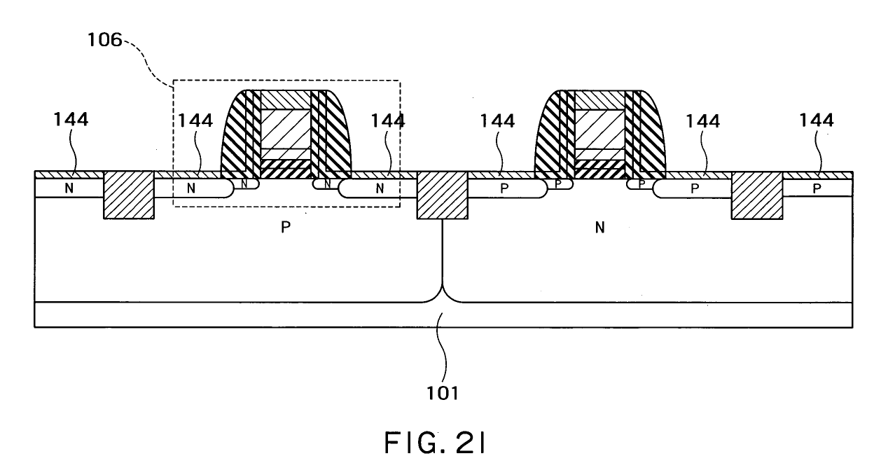

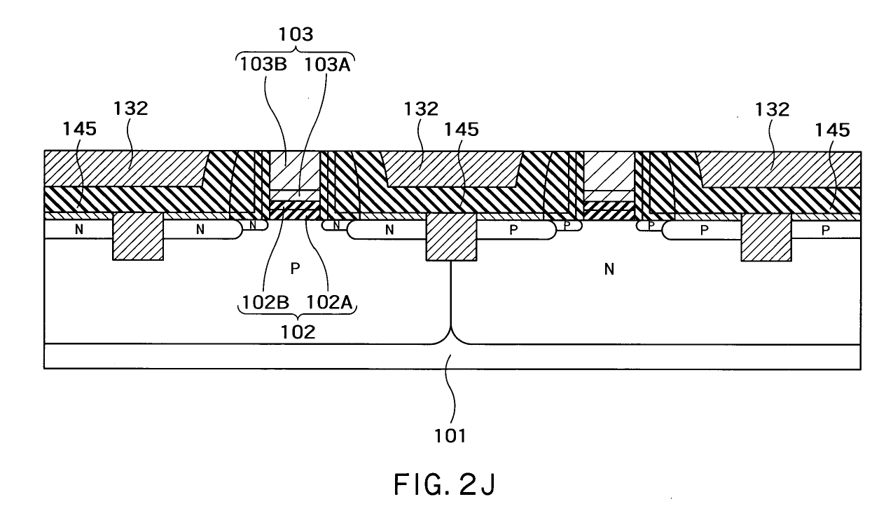

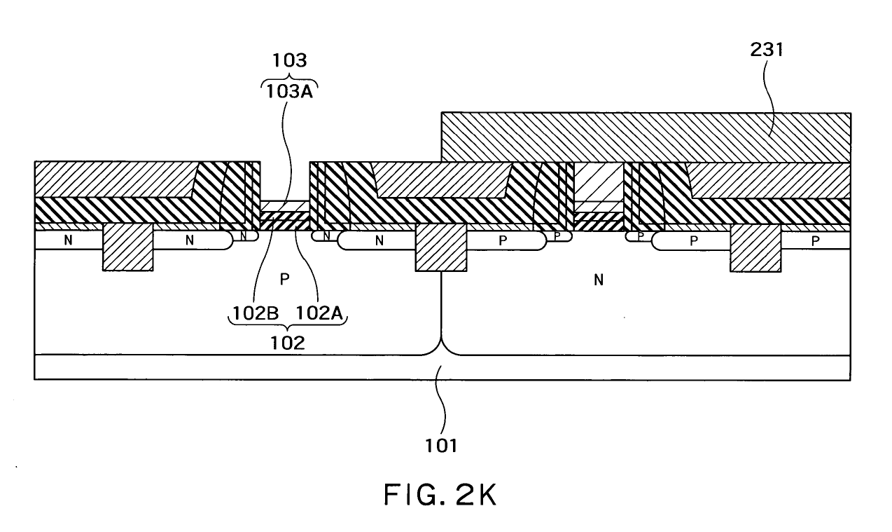

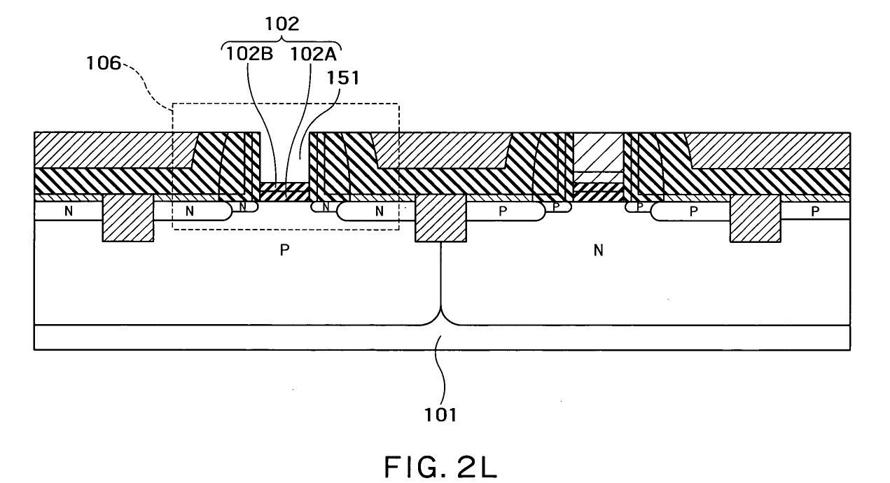

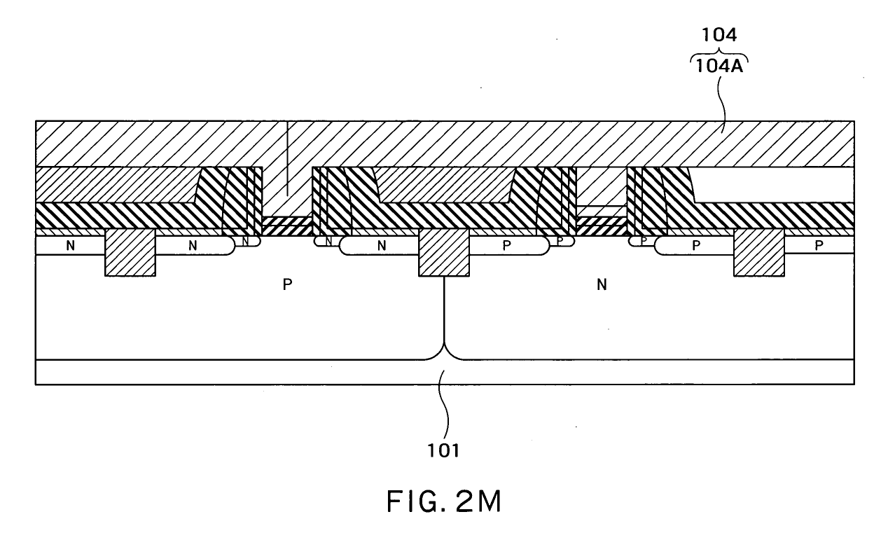

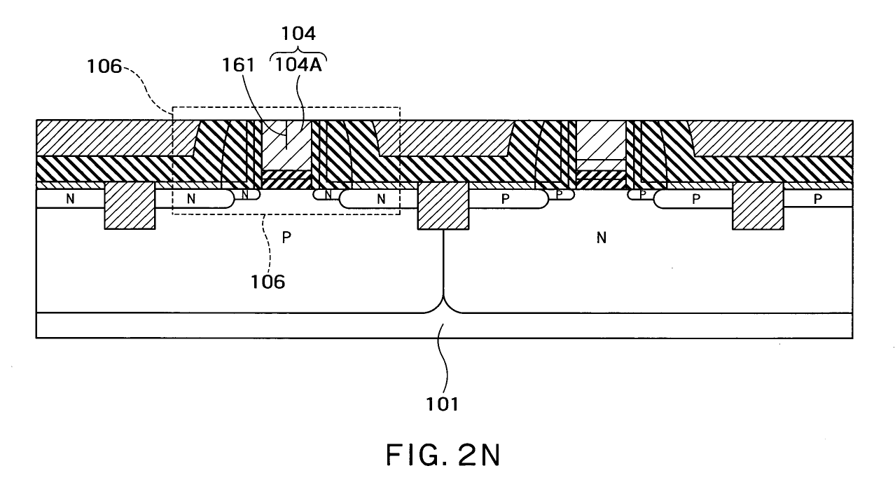

FIGS. 2A to 2N are side sectional views showing a method for manufacturing the semiconductor device of the first embodiment.

First, as shown in FIG. 2A, silicon oxide films are buried in predetermined regions of a silicon substrate 101 to form isolation layers 131 of STIs. Then, as shown in FIG. 2A, a silicon oxide film (dielectric film) 201 is formed on the silicon substrate 101.

Next, as shown in FIG. 2B, ions of P (phosphorus) are implanted into the substrate 101 using a resist 211 as a mask. The implantation of P ions is performed to form the well diffusion layer 111 for the PMOSFET and to adjust the threshold voltage of the PMOSFET, and performed a plurality of times. In some cases, ions of B (boron), In (indium), or the like are further implanted to finely adjust the threshold voltage of the PMOSFET.

Next, as shown in FIG. 2C, ions of B (boron) are implanted into the substrate 101 using a resist 221 as a mask. The implantation of B ions is performed to form the well diffusion layer 121 for the NMOSFET and to adjust the threshold voltage of the NMOSFET, and performed a plurality of times. In some cases, ions of P (phosphorus), As (arsenic), or the like are further implanted to finely adjust the threshold voltage of the NMOSFET. After that, the substrate 101 is subjected to thermal diffusion processing, thereby completing the well diffusion layer 111 for the PMOSFET and the well diffusion layer 121 for the NMOSFET.

Next, as shown in FIG. 2D, the dielectric film 201 is removed from the substrate 101 using an ammonium fluoride aqueous solution, and the surface of the substrate 101 is cleaned using 0.5 to 5.0% hydrofluoric acid. Then, as shown in FIG. 2D, a silicon oxide film (a first dielectric film of a gate dielectric film) 102A with a thickness of 0.5 to 0.8 nm is formed on the substrate 101 in an atmosphere containing oxygen, and a hafnium silicate film (a second dielectric film of the gate dielectric film) 102B with a thickness of about 2.0 nm is formed on the silicon oxide film 102A using tetrakis(diethylamino)hafnium, tetrakis(dimethylamino)silicon, and oxygen. After that, the substrate 101 is subjected to annealing at 600° C., thereby densifying the silicon oxide film 102A and hafnium silicate film 102B. After that, the substrate 101 is processed in a nitrogen plasma atmosphere or ammonia atmosphere and then subjected to annealing at 1,000° C., thereby reforming the hafnium silicate film 102B into a hafnium silicon oxynitride film 102B. With the above-described manufacturing steps, the gate dielectric film 102 common to the PMOSFET and the NMOSFET is formed, ranging from a PMOSFET region 105 to a NMOSFET region 106, on the substrate 101. The PMOSFET region 105 is a region where the PMOSFET is to be formed, which is a specific example of a P-type FET region, and the NMOSFET region 106 is a region where the NMOSFET is to be formed, which is a specific example of an N-type FET region.

Note that although the gate dielectric film 102 of the first embodiment has a two-layer structure of the silicon oxide film 102A and hafnium silicon oxynitride film 102B, it may have a one-layer structure of only a hafnium silicon oxynitride film or a laminated structure of three or more layers including a hafnium silicon oxynitride film.

Next, as shown in FIG. 2E, a Ru (ruthenium) layer (a first conductive layer of a gate electrode for the PMOSFET) 103A with a thickness of about 20 nm is deposited on the hafnium silicon oxynitride film 102B using bis(cyclopentadienyl)ruthenium and oxygen, and a W (tungsten) layer (a second conductive layer of the gate electrode for the PMOSFET) 103B with a thickness of about 60 nm is deposited on the Ru layer 103A using tungsten hexafluoride, silane, and hydrogen. With the above-described manufacturing steps, the gate electrode layer 103 for the PMOSFET is formed, ranging from the PMOSFET region 105 to the NMOSFET region 106, on the gate dielectric film 102.

Note that although the gate electrode layer 103 for the PMOSFET of the first embodiment has a two-layer structure of the Ru layer 103A and W layer 103B, it may have a one-layer structure of only a Ru layer or a laminated structure of three or more layers including a Ru layer. The two-layer structure of the gate electrode layer 103 for the PMOSFET of the first embodiment is mainly due to the thickness of the Ru layer 103A. Since Ru has not only advantages such as a high work function but also disadvantages such as costliness, the thickness of the Ru layer 103A is made small in the first embodiment. For this reason, in the first embodiment, migration and even agglomeration may occur in the Ru layer 103A, for example, at the time of activation of the source/drain diffusion layer due to the tension of the Ru layer 103A itself. To prevent these phenomena, the gate electrode layer 103 for the PMOSFET is configured to have a two-layer structure in the first embodiment.

Next, as shown in FIG. 2F, the Ru layer 103A and W layer 103B are processed using a dielectric film 202 as a hard mask, the dielectric film 202 including a silicon oxide film or silicon nitride film. The dielectric film 202 is deposited and processed to be the hard masks in advance. With the above-described manufacturing steps, in the PMOSFET region 105 and the NMOSFET region 106, a gate electrode 103 for the PMOSFET is formed in the PMOSFET region 105, and a dummy gate electrode (a gate electrode used as a dummy) 103 with the same configuration as that of the gate electrode 103 for the PMOSFET is formed in the NMOSFET region 106.

Next, as shown in FIG. 2G, the silicon oxide film 102A and hafnium silicon oxynitride film 102B are processed using the dielectric film 202 as a hard mask. Etching conditions at this time are determined by appropriately selecting an etchant and etching time in consideration of the thickness and type of the high-permittivity dielectric film such that all of each dielectric film 202 is not etched. With the above-described manufacturing steps, in the PMOSFET region 105 and the NMOSFET region 106, a gate dielectric film 102 for the PMOSFET is formed in the PMOSFET region 105, and a gate dielectric film 102 for the NMOSFET is formed in the NMOSFET region 106. Gate dielectric films 102 for the PMOSFET and the NMOSFET are formed from the gate dielectric film 102 common to the PMOSFET and the NMOSFET.

Next, an offset spacer 141 made of a silicon oxide film or silicon nitride film and a side wall spacer 142 made of a silicon oxide film, are formed on the lateral surface of each gate electrode and gate dielectric film by CVD and RIE. Then, ions of B are implanted into the well diffusion layer 111 for the PMOSFET, ions of P or As are implanted into the well diffusion layer 121 for the NMOSFET, and the substrate 101 is subjected to annealing at 1,000° C.; with this process, the source/drain diffusion layer 112 for the PMOSFET and the source/drain diffusion layer 122 for the NMOSFET are formed, as shown in FIG. 2H. Also, ions of B are implanted into the well diffusion layer 111 for the PMOSFET, ions of P or As are implanted into the well diffusion layer 121 for the NMOSFET, and the substrate 101 is subjected to annealing at 1,000° C.; with this process, the extension diffusion layer 113 for the PMOSFET and the extension diffusion layer 123 for the NMOSFET are formed, as shown in FIG. 2H. In some cases, halo implantation is further performed to suppress short channel effects. Then, side wall spacers 143, each of which is made of a silicon nitride film, are formed by CVD and RIE. With the above-described manufacturing steps, in the PMOSFET region 105 and NMOSFET region 106, the source/drain diffusion layer 112 and extension diffusion layer 113 for the PMOSFET and the source/drain diffusion layer 122 and extension diffusion layer 123 for the NMOSFET are formed in the substrate 101.

Note that although each side wall spacer of the first embodiment has a two-layer structure of the first side wall spacer 142 made of the silicon oxide film and the second side wall spacer 143 made of the silicon nitride film, it may have a one-layer structure, for example, of only a silicon nitride film or a laminated structure of three or more layers including, for example, a silicon oxide film and silicon nitride film.

Next, as shown in FIG. 2I, silicide films 144 are formed in a self-aligned manner on the surfaces of the source/drain diffusion layer 112 for the PMOSFET and the source/drain diffusion layer 122 for the NMOSFET. Although NiSi films are adopted as the silicide films 144 in this embodiment, PtSi films, ErSi films, NiPtSi films, NiErSi films, or the like may be adopted as the silicide films 144 instead.

Next, as shown in FIG. 2J, an etch stopper film 145 made of a silicon nitride film is formed over the entire surface by CVD. Then, as shown in FIG. 2J, an inter layer dielectric film 132 made of a silicon oxide film is formed over the entire surface. Then, as shown in FIG. 2J, the surface of the substrate 101 is planarized by chemical mechanical polishing or etching (dry etching or wet etching). With the above-described manufacturing steps, the W layers 103B are exposed both in the PMOSFET region 105 and the NMOSFET region 106.

Next, as shown in FIG. 2K, in the NMOSFET region 106, the W layer 103B above the gate dielectric film 102 for the NMOSFET is etched using a resist 231 as a mask and using a chemical solution such as a solution containing hydrogen peroxide. With the above-described manufacturing step, the Ru layer 103A in the NMOSFET region 106 is exposed.

Next, as shown in FIG. 2L, in the NMOSFET region 106, the Ru layer 103A on the gate dielectric film 102 for the NMOSFET is etched in an atmosphere containing oxygen radical. With the above-described manufacturing step, the hafnium silicon oxynitride film 102B in the NMOSFET region 106 is exposed. The resist 231 may be removed before or after the removal of the Ru layer 103A. Through the above-described manufacturing steps, in the NMOSFET region 106, the dummy gate electrode 103 on the gate dielectric film 102 is removed, thereby forming a trench 151 on the gate dielectric film 102.

Next, as shown in FIG. 2M, conductive metal, which is a material for forming a third conductive layer 104A of the gate electrode 104 for the NMOSFET, is deposited over the entire surface by CVD. Examples of the conductive metal include TaSiN which is formed using pentakis(ethylmethylamino)tantalum, disilane, and ammonia, HfN which is formed in an atmosphere containing tetrakis(ethylmethylamino)hafnium and ammonia, HfSi which is formed using tetrakis(ethylmethylamino)hafnium and tetrakis(ethylmethylamino)silicon, and WSi which is formed using tungsten hexafluoride and dichlorosilane.

Note that although the gate electrode 104 for the NMOSFET of the first embodiment has a one-layer structure of only the conductive layer 104A made of the conductive metal, it may have a laminated structure of two or more layers including a conductive layer made of conductive metal.

Next, as shown in FIG. 2N, the surface of the substrate 101 is planarized by chemical mechanical polishing or etching (etchback). Through the above-described manufacturing steps, in the NMOSFET region 106, the material for forming the gate electrode is buried in the trench 151 on the gate dielectric film 102, thereby forming the gate electrode 104 for the NMOSFET with a different configuration from that of the gate electrode 103 for the PMOSFET. Since the gate electrode 104 for the NMOSFET (the third conductive layer 104A) is formed in the hole by CVD, a trace of a streaky seam 161 which does not remain in the gate electrode 103 for the PMOSFET (the first conductive layer 103A and second conductive layer 103B) remains in the gate electrode 104 for the NMOSFET.

After that, the substrate 101 is subjected to steps of forming a wiring layer, an inter layer dielectric film between wiring layers, a contact hole, a via hole, a plug layer, and the like as appropriate, and the semiconductor device is finally completed.

As described above, in the semiconductor device of the first embodiment, each gate dielectric film 102 is a high-permittivity gate dielectric film, all or a part of which is made of the high-permittivity dielectric film, the gate electrode 103 for the PMOSFET is a metal gate electrode, all or a part of which is made of the conductive metal, and the gate electrode 104 for the NMOSFET is a metal gate electrode, all or a part of which is made of the conductive metal. Accordingly, in the first embodiment, it is possible to thin the gate dielectric films while suppressing an increase in leakage current, and to suppress a shift in the threshold voltage of the PMOSFET to increase the inversion capacitance of the PMOSFET.

Moreover, in the first embodiment, since the source/drain diffusion layer 112 (and the extension diffusion layer 113) for the PMOSFET and the source/drain diffusion layer 122 (and extension diffusion layer 123) for the NMOSFET are formed after formation of the gate dielectric films 102, it is possible to improve the quality of the high-permittivity dielectric films to suppress a leakage current in them. This is because performing the process of improving the quality of the high-permittivity dielectric films before the formation of the source/drain diffusion layers (and extension diffusion layers) makes it possible, to perform the process of improving the quality of the high-permittivity dielectric films without concern about adverse effects on the source/drain diffusion layers (and extension diffusion layers).

Moreover, in the first embodiment, the gate electrode 104 for the NMOSFET is formed after the source/drain diffusion layer 112 (and extension diffusion layer 113) for the PMOSFET and the source/drain diffusion layer 122 (and extension diffusion layer 123) for the NMOSFET are formed. Accordingly, the possibility of change in the work function of the metal electrode of the NMOSFET in the step of forming the source/drain diffusion layers (and extension diffusion layers) is reduced.

Therefore, in the first embodiment, gate dielectric films with preferable characteristics such as a preferable film quality, and gate electrodes with preferable characteristics such as a preferable work function, can be used as gate dielectric films and gate electrodes constituting a PMOSFET and an NMOSFET. Accordingly, in the first embodiment, it is possible to manufacture a semiconductor device including a high-performance CMOSFET.

Additionally, in the first embodiment, the gate electrode 103 for the PMOSFET is formed by etching before formation of the inter layer dielectric film 132, and the gate electrode 104 for the NMOSFET is formed by the damascene process after formation of the inter layer dielectric film 132. Further, in the first embodiment, the gate electrode 103 for the PMOSFET formed in the NMOSFET region is used as a dummy electrode substituting for the gate electrode 104 for the NMOSFET. Therefore, in the first embodiment, the gate electrode 103 for the PMOSFET formed in the NMOSFET region is not wastefully removed in the etching step, and effectively used as the dummy electrode substituting for the gate electrode 104 for the NMOSFET until it is removed prior to the damascene process. Furthermore, in the first embodiment, since the step of forming the dummy electrode is integrated into the step of forming the gate electrode 103 for the PMOSFET, the number of steps required for the formation of the dummy electrode can be saved.

In the damascene gate process explained as a background art, a dummy gate dielectric film (silicon oxide) is damaged in removing a dummy gate electrode (polysilicon), so it is necessary to remove also the dummy gate dielectric film in removing the dummy gate electrode. However, in the first embodiment, the dummy electrode in contact with the gate dielectric film 102 (second dielectric film 102B) made of the high-permittivity dielectric film, is the gate electrode 103 for the PMOSFET (first conductive layer 103A) made of the conductive metal. Particularly, in the first embodiment, the conductive metal is Ru, which is conductive metal capable of being removed without a chemical solution. Accordingly, in the first embodiment, it is possible to avoid unnecessary damage to the gate dielectric film 102 and unnecessary removal of the gate dielectric film 102, in removing the dummy electrode.

Although, in this embodiment, a hafnium silicon oxynitride film is adopted as a high-permittivity dielectric film to form each gate dielectric film 102, any other high-permittivity dielectric film may be adopted. Although, in this embodiment, the Ru layer and W layer are adopted as metal electrode layers to form the gate electrode 103 for the PMOSFET, any other metal electrode layers may be adopted. For example, a W layer, Ru layer, or Pt layer may be adopted as a metal electrode layer to form the gate electrode 103 for the PMOSFET. Although, in this embodiment, a TaSiN layer, HfN layer, and WSi layer are described as examples of metal electrode layers to form the gate electrode 104 for the NMOSFET, any other metal electrode layers may be adopted. It is possible to adopt, for example, a TaSi layer, TaSiN layer, TaC layer, TaCN layer, TaSiCN layer, HfN layer, HfSi layer, HfSiN layer, WSi layer, TaHf layer, or TaHfN layer as a metal electrode layer to form the gate electrode 104 for the NMOSFET.

The first embodiment has been explained above. A second embodiment and a third embodiment will be explained below. Each of the second and third embodiments is a variation of the first embodiment, and each of the second and third embodiments will be explained with a focus on differences from the first embodiment.

### Second Embodiment

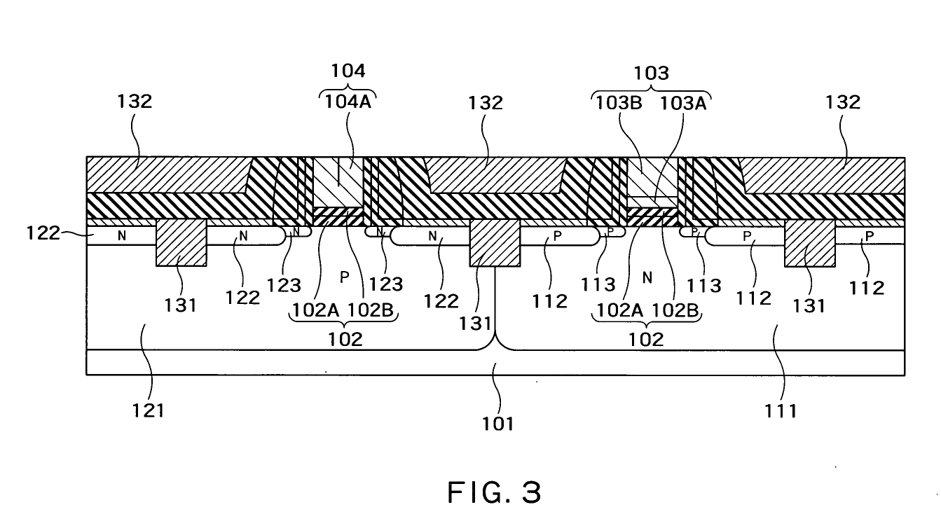

FIG. 3 is a side sectional view showing a semiconductor device according to the second embodiment. The semiconductor device in FIG. 3 includes a PMOSFET which is a specific example of a P-type FET and an NMOSFET which is a specific example of an N-type FET. The semiconductor device in FIG. 3 includes a CMOSFET which is constituted by the PMOSFET and the NMOSFET.

The semiconductor device shown in FIG. 3 includes a substrate 101, gate dielectric films 102, a gate electrode 103 for the PMOSFET, and a gate electrode 104 for the NMOSFET. The substrate 101 is a semiconductor substrate, all or a part of which is made of a semiconductor. The substrate 101 in this embodiment is a silicon substrate, all or a part of which is made of silicon. Each gate dielectric film 102 is a high-permittivity gate dielectric film, all or a part of which is made of a high-permittivity dielectric film. Each gate dielectric film 102 in this embodiment includes two layers of dielectric films: a first dielectric film 102A which is a silicon oxide film and a second dielectric film 102B which is a high-permittivity dielectric film. The gate electrode 103 for the PMOSFET is a metal gate electrode, all or a part of which is made of conductive metal. The gate electrode 103 for the PMOSFET in this embodiment includes two electrode-constituting layers: a first conductive layer 103A which is made of conductive metal and a second conductive layer 103B which is made of conductive metal. The gate electrode 104 for the NMOSFET is a metal gate electrode, all or a part of which is made of conductive metal. The gate electrode 104 for the NMOSFET in this embodiment includes one electrode-constituting layer: a third conductive layer 104A which is made of conductive metal.

Additionally, the semiconductor device shown in FIG. 3 has, as diffusion layers for the PMOSFET, a well diffusion layer 111 for the PMOSFET, a source/drain diffusion layer 112 for the PMOSFET, and an extension diffusion layer 113 for the PMOSFET.

Additionally, the semiconductor device shown in FIG. 3 has, as diffusion layers for the NMOSFET, a well diffusion layer 121 for the NMOSFET, a source/drain diffusion layer 122 for the NMOSFET, and an extension diffusion layer 123 for the NMOSFET.

Additionally, the semiconductor device shown in FIG. 3 has an isolation layer 131 for intervening between the source/drain diffusion layer 112 for the PMOSFET and the source/drain diffusion layer 122 for the NMOSFET, and an inter layer dielectric film 132 for intervening between the PMOSFET and the NMOSFET. The isolation layer 131 in this embodiment is an STI layer which is made of a silicon oxide film, and the inter layer dielectric film 132 in this embodiment is a silicon oxide film.

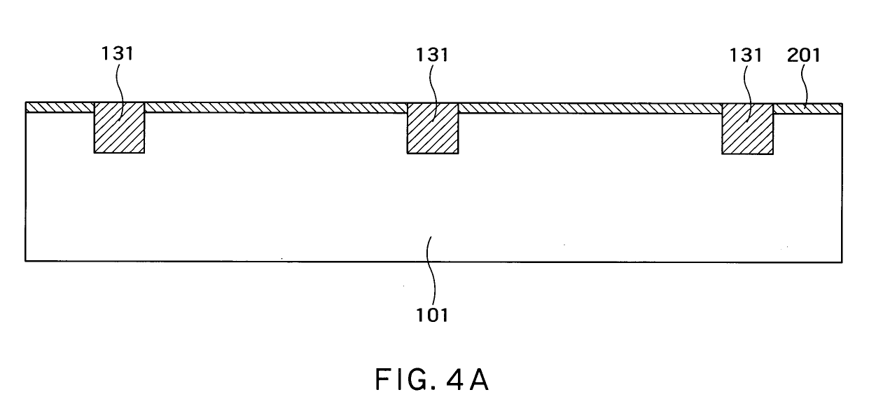

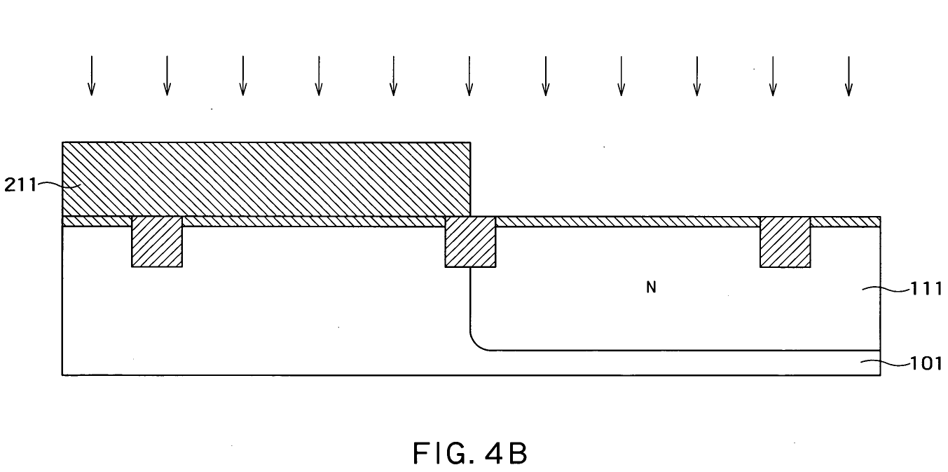

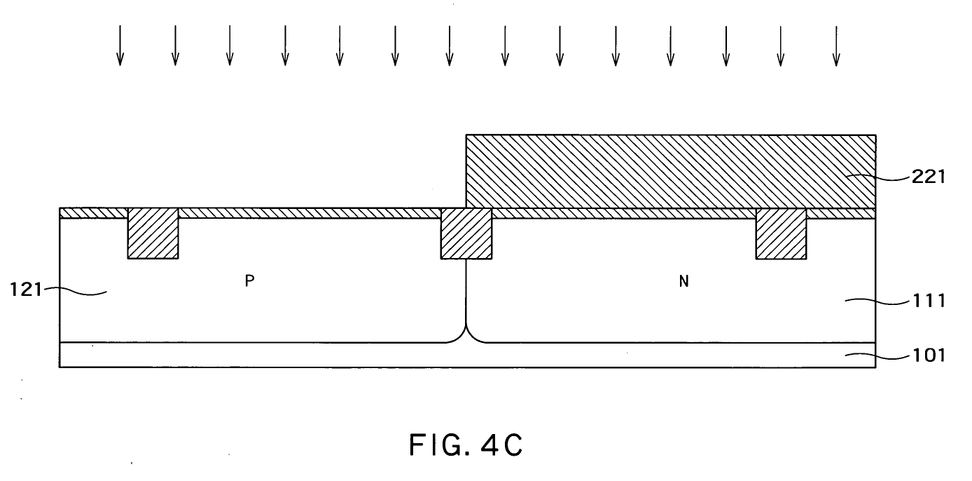

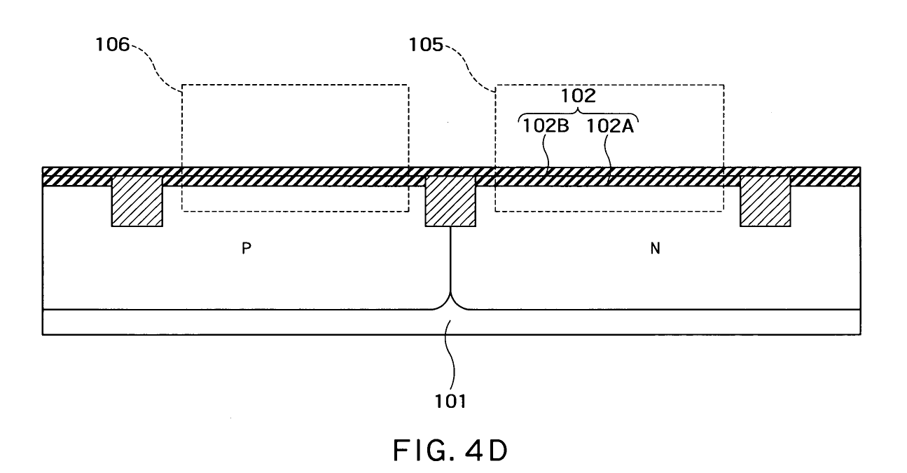

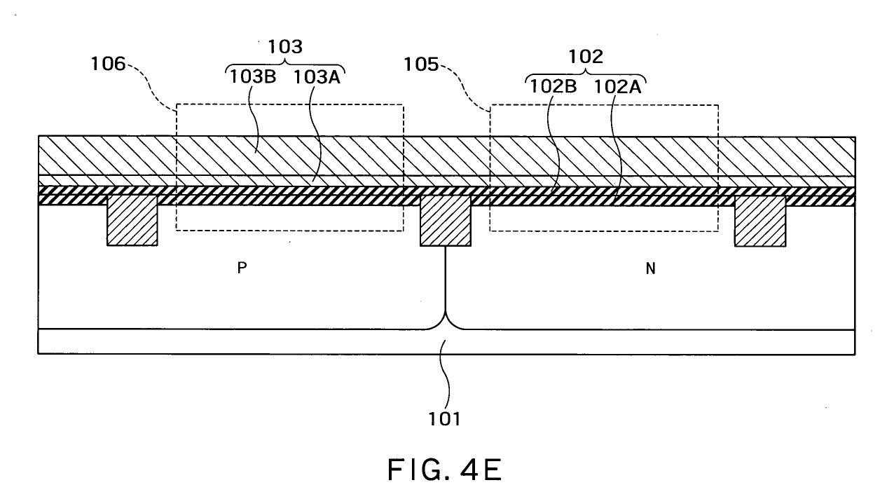

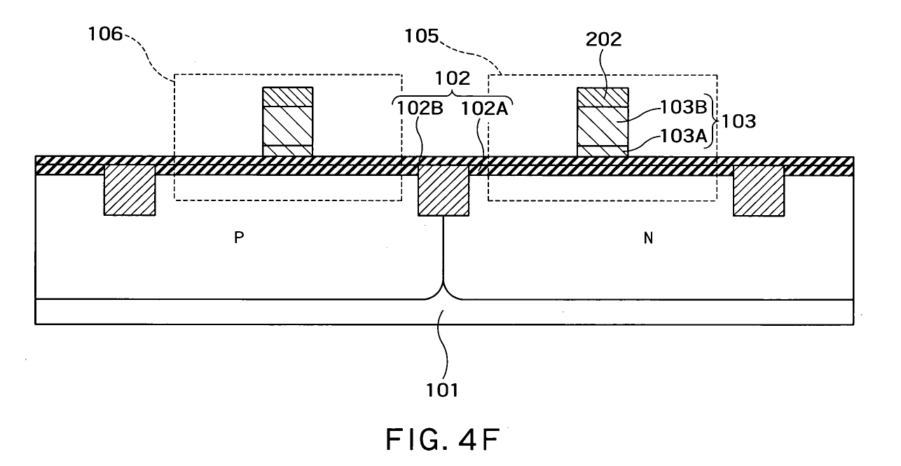

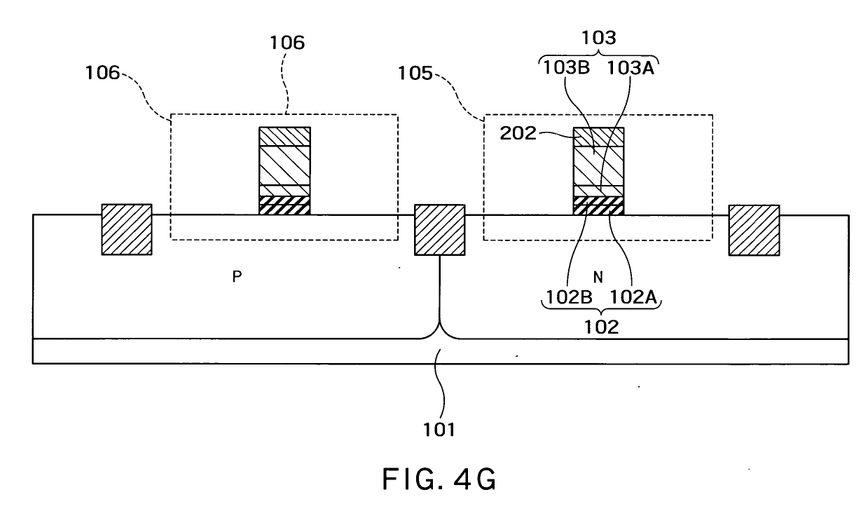

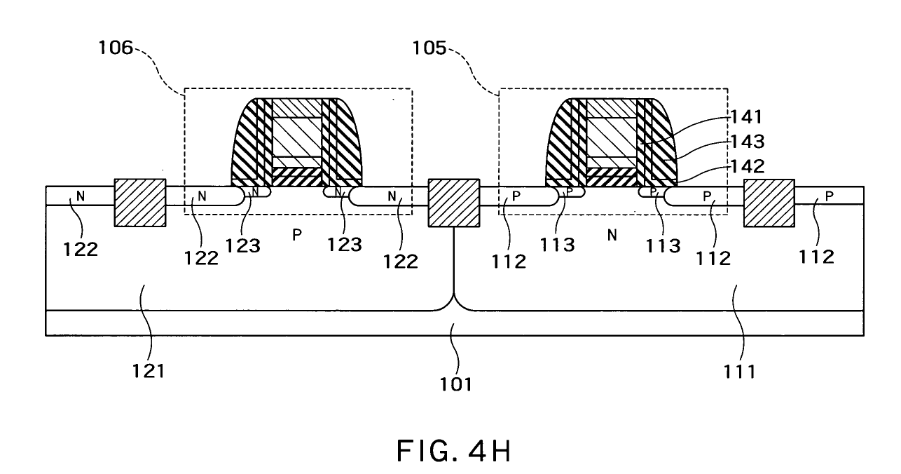

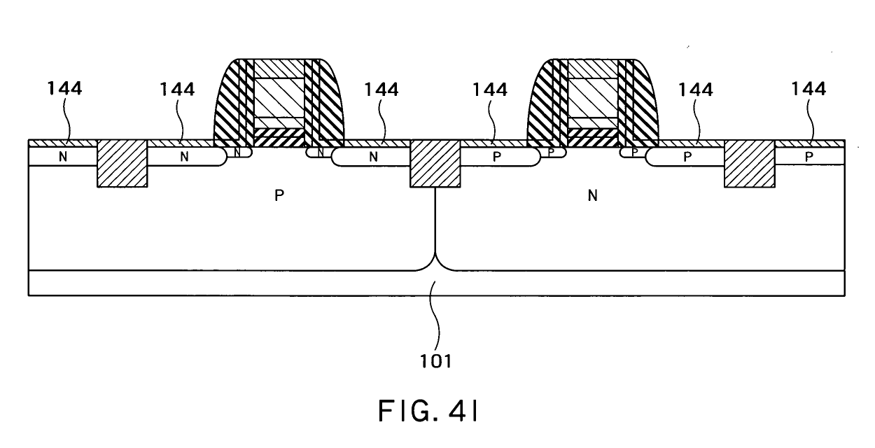

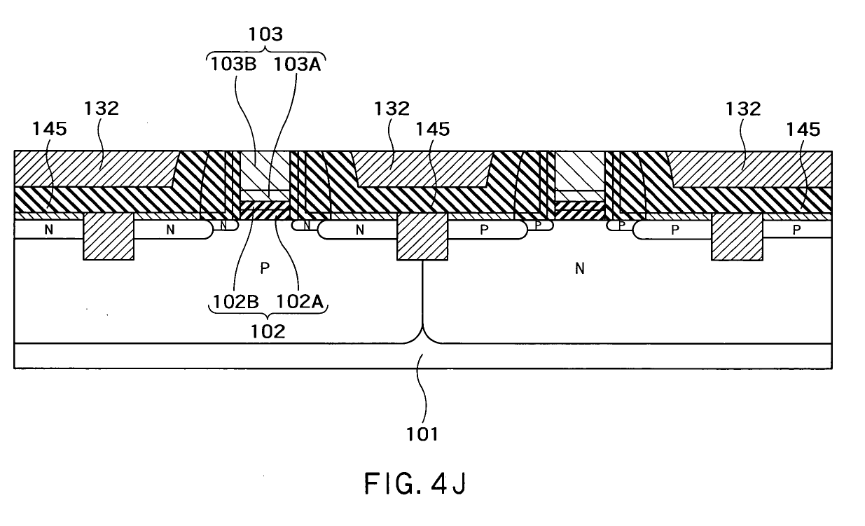

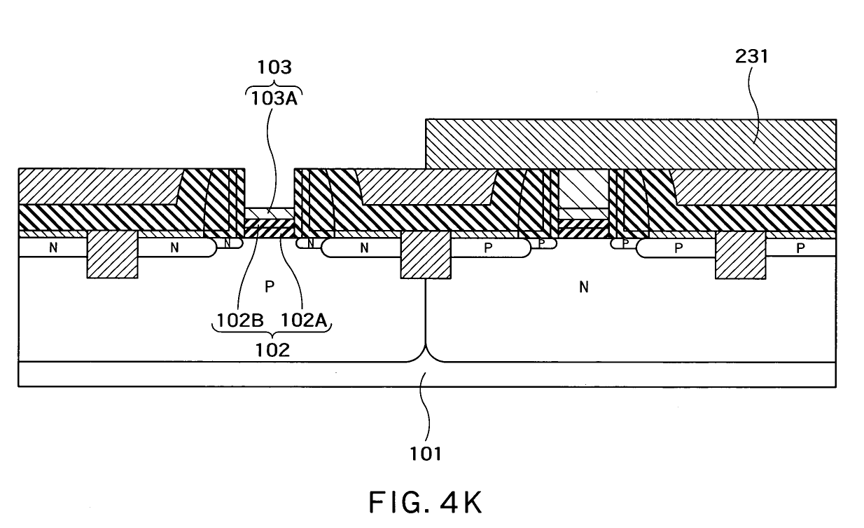

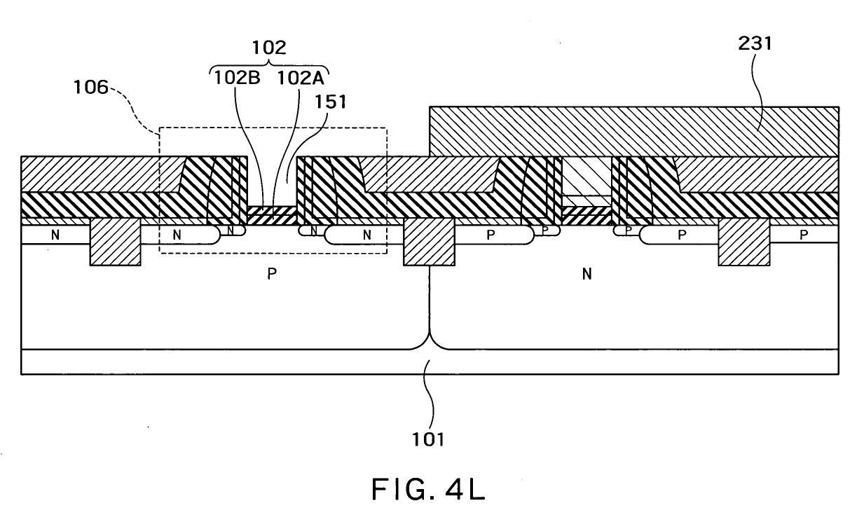

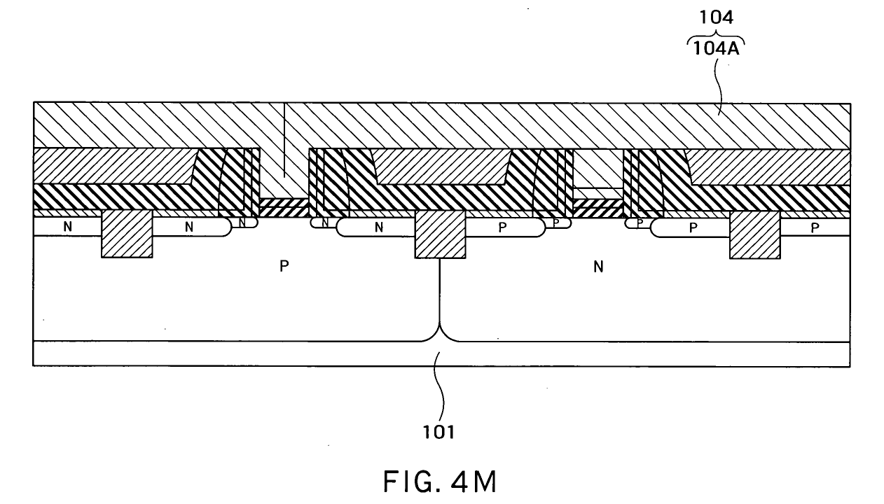

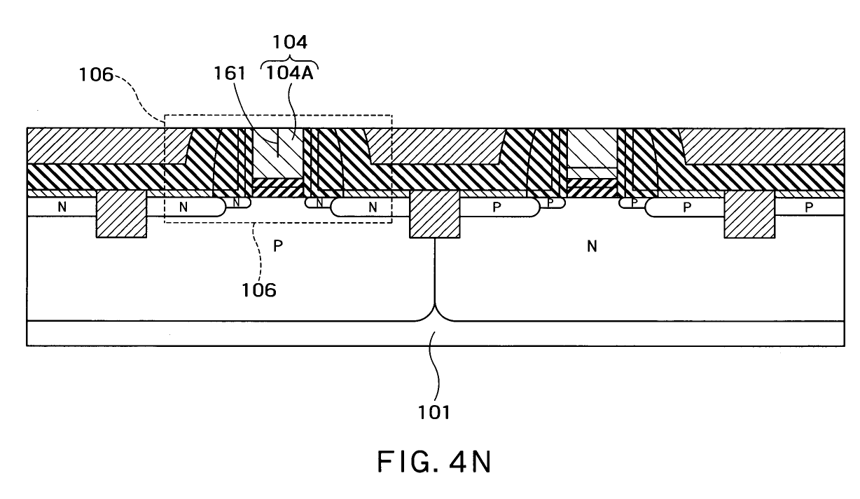

FIGS. 4A to 4N are side sectional views showing a method for manufacturing the semiconductor device of the second embodiment.

First, as shown in FIG. 4A, silicon oxide films are buried in predetermined regions of a silicon substrate 101 to form isolation layers 131 of STIs. Then, as shown in FIG. 4A, a silicon oxide film (dielectric film) 201 is formed on the silicon substrate 101.

Next, as shown in FIG. 4B, ions of P (phosphorus) are implanted into the substrate 101 using a resist 211 as a mask.

Next, as shown in FIG. 4C, ions of B (boron) are implanted into the substrate 101 using a resist 221 as a mask. After that, the substrate 101 is subjected to thermal diffusion processing, thereby completing a well diffusion layer 111 for the PMOSFET and a well diffusion layer 121 for the NMOSFET.

Next, as shown in FIG. 4D, the dielectric film 201 is removed from the substrate 101 using an ammonia fluoride aqueous solution, and the surface of the substrate 101 is cleaned using 0.5 to 5.0% hydrofluoric acid. Then, as shown in FIG. 4D, a silicon oxide film (a first dielectric film of a gate dielectric film) 102A with a thickness of 0.5 to 0.8 nm is formed on the substrate 101 in an atmosphere containing oxygen, and a hafnium silicate film (a second dielectric film of the gate dielectric film) 102B with a thickness of about 2.0 nm is formed on the silicon oxide film 102A using tetrakis(diethylamino)hafnium, tetrakis(dimethylamino)silicon, and oxygen. After that, the substrate 101 is subjected to annealing at 600° C., thereby densifying the silicon oxide film 102A and hafnium silicate film 102B. After that, the substrate 101 is processed in a nitrogen plasma atmosphere or ammonia atmosphere and then subjected to annealing at 1,000° C., thereby reforming the hafnium silicate film 102B into a hafnium silicon oxynitride film 102B. With the above-described manufacturing steps, the gate dielectric film 102 common to the PMOSFET and NMOSFET is formed, ranging from a PMOSFET region 105 to a NMOSFET region 106, on the substrate 101. The PMOSFET region 105 is a region where the PMOSFET is to be formed, which is a specific example of a P-type FET region, and the NMOSFET region 106 is a region where the NMOSFET is to be formed, which is a specific example of an N-type FET region.

Note that although the gate dielectric film 102 of the second embodiment has a two-layer structure of the silicon oxide film 102A and hafnium silicon oxynitride film 102B, it may have a one-layer structure of only a hafnium silicon oxynitride film or a laminated structure of three or more layers including a hafnium silicon oxynitride film.

Next, as shown in FIG. 4E, a W (tungsten) layer (a first conductive layer of a gate electrode for the PMOSFET) 103A with a thickness of about 20 nm is deposited on the hafnium silicon oxynitride film 102B by thermal CVD using tungsten hexacarbonyl or plasma CVD using tungsten hexacarbonyl and hydrogen, and a TiN (titanium nitride) layer (a second conductive layer of the gate electrode for the PMOSFET) 103B with a thickness of about 60 nm is deposited on the W layer 103A using titanium tetrachloride and ammonia. With the above-described manufacturing steps, the gate electrode layer 103 for the PMOSFET is formed, ranging from the PMOSFET region 105 to the NMOSFET region 106, on the gate dielectric film 102.

Note that although the gate electrode layer 103 for the PMOSFET of the second embodiment has a two-layer structure of the W layer 103A and TiN layer 103B, it may have a one-layer structure of only a W layer or a laminated structure of three or more layers including a W layer. If the gate electrode layer 103 for the PMOSFET has a one-layer structure of only a W layer, it is desirable to reduce the thickness of the W layer to 60 nm or less because the W layer is likely to peel off.

Next, as shown in FIG. 4F, the W layer 103A and TiN layer 103B are processed using a dielectric film 202 as a hard mask, the dielectric film 202 including a silicon oxide film or silicon nitride film. With the above-described manufacturing step, in the PMOSFET region 105 and the NMOSFET region 106, a gate electrode 103 for the PMOSFET is formed in the PMOSFET region 105, and a dummy gate electrode (a gate electrode used as a dummy) 103 with the same configuration as that of the gate electrode 103 for the PMOSFET is formed in the NMOSFET region 106.

Next, as shown in FIG. 4G, the silicon oxide film 102A and hafnium silicon oxynitride film 102B are processed using the dielectric film 202 as a hard mask. With the above-described manufacturing steps, in the PMOSFET region 105 and the NMOSFET region 106, a gate dielectric film 102 for the PMOSFET is formed in the PMOSFET region 105, and a gate dielectric film 102 for the NMOSFET is formed in the NMOSFET region 106. Gate dielectric films 102 for the PMOSFET and the NMOSFET are formed from the gate dielectric film 102 common to the PMOSFET and the NMOSFET.

Next, an offset spacer 141 made of a silicon oxide film or silicon nitride film and a side wall spacer 142 made of a silicon oxide film, are formed on the lateral surface of each gate electrode and gate dielectric film by CVD and RIE. Then, ions of B are implanted into the well diffusion layer 111 for the PMOSFET, ions of P or As are implanted into the well diffusion layer 121 for the NMOSFET, and the substrate 101 is subjected to annealing at 1,000° C.; with this process, the source/drain diffusion layer 112 for the PMOSFET and the source/drain diffusion layer 122 for the NMOSFET are formed, as shown in FIG. 4H. Also, ions of B are implanted into the well diffusion layer 111 for the PMOSFET, ions of P or As are implanted into the well diffusion layer 121 for the NMOSFET, and the substrate 101 is subjected to annealing at 1,000° C.; with this process, the extension diffusion layer 113 for the PMOSFET and the extension diffusion layer 123 for the NMOSFET are formed, as shown in FIG. 4H. Then, side wall spacers 143, each of which is made of a silicon nitride film, are formed by CVD and RIE. With the above-described manufacturing steps, in the PMOSFET region 105 and NMOSFET region 106, the source/drain diffusion layer 112 and extension diffusion layer 113 for the PMOSFET and the source/drain diffusion layer 122 and extension diffusion layer 123 for the NMOSFET are formed in the substrate 101.

Next, as shown in FIG. 4I, silicide films 144 are formed in a self-aligned manner on the surfaces of the source/drain diffusion layer 112 for the PMOSFET and the source/drain diffusion layer 122 for the NMOSFET.

Next, as shown in FIG. 4J, an etch stopper film 145 made of a silicon nitride film is formed over the entire surface by CVD. Then, as shown in FIG. 4J, an inter layer dielectric film 132 made of a silicon oxide film is formed over the entire surface. Then, as shown in FIG. 4J, the surface of the substrate 101 is planarized by chemical mechanical polishing or etching (dry etching or wet etching). With the above-described manufacturing steps, the TiN layers 103B are exposed both in the PMOSFET region 105 and the NMOSFET region 106.

Next, as shown in FIG. 4K, in the NMOSFET region 106, the TiN layer 103B above the gate dielectric film 102 for the NMOSFET is etched using a resist 231 as a mask and using a chemical solution such as a solution containing hydrogen peroxide. With the above-described manufacturing step, the W layer 103A in the NMOSFET region 106 is exposed.

Next, as shown in FIG. 4L, in the NMOSFET region 106, the W layer 103A on the gate dielectric film 102 for the NMOSFET is etched using the resist 231 as a mask and using a chemical solution such as a solution containing hydrogen peroxide. With the above-described manufacturing step, the hafnium silicon oxynitride film 102B in the NMOSFET region 106 is exposed. Through the above-described manufacturing steps, in the NMOSFET region 106, the dummy gate electrode 103 on the gate dielectric film 102 is removed, thereby forming a trench 151 on the gate dielectric film 102.

Next, as shown in FIG. 4M, conductive metal, which is a material for forming a third conductive layer 104A of the gate electrode 104 for the NMOSFET, is deposited over the entire surface by CVD. Examples of the conductive metal include TaC, which is formed using pentakis(dimethylamino)tantalum and methane.

Note that although the gate electrode 104 for the NMOSFET of the second embodiment has a one-layer structure of only the conductive layer 104A made of the conductive metal, it may have a laminated structure of two or more layers including a conductive layer made of conductive metal.

Next, as shown in FIG. 4N, the surface of the substrate 101 is planarized by chemical mechanical polishing or etching (etchback). Through the above-described manufacturing steps, in the NMOSFET region 106, the material for forming the gate electrode is buried in the trench 151 on the gate dielectric film 102, thereby forming the gate electrode 104 for the NMOSFET with a different configuration from that of the gate electrode 103 for the PMOSFET. Since the gate electrode 104 for the NMOSFET (the third conductive layer 104A) is formed in the hole by CVD, a trace of a streaky seam 161 which does not remain in the gate electrode 103 for the PMOSFET (the first conductive layer 103A and second conductive layer 103B) remains in the gate electrode 104 for the NMOSFET.

After that, the substrate 101 is subjected to steps of forming a wiring layer, an inter layer dielectric film between wiring layers, a contact hole, a via hole, a plug layer, and the like as appropriate, and the semiconductor device is finally completed.

In the second embodiment, the dummy electrode (the gate electrode 103 for the PMOSFET) includes the W layer 103A and TiN layer 103B made of W and TiN respectively, which are conductive metals capable of being removed using a chemical solution. For this reason, in the second embodiment, it is possible to easily remove the dummy electrode at low cost.

The first embodiment and the second embodiment have been explained above. The third embodiment will be explained below. The third embodiment is a variation of the first and second embodiments, and the third embodiment will be explained with a focus on differences from the first and second embodiments.

### Third Embodiment

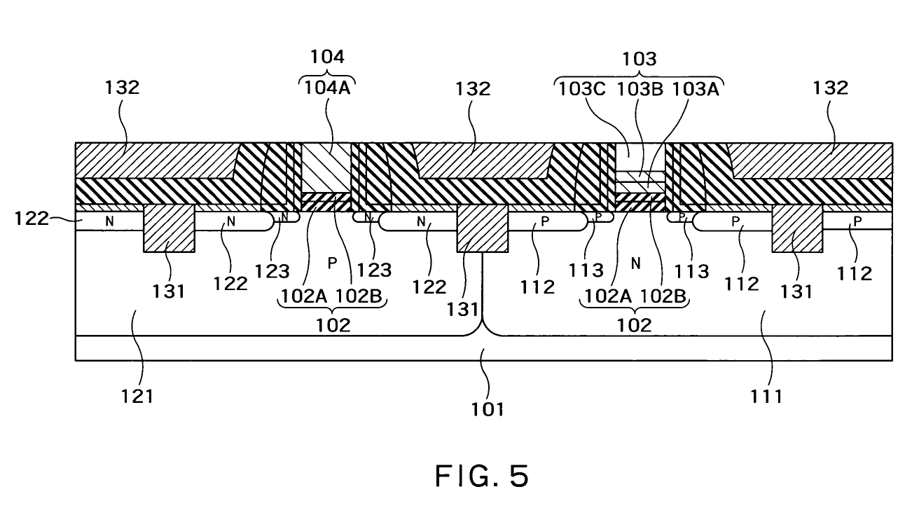

FIG. 5 is a side sectional view showing a semiconductor device according to a third embodiment. The semiconductor device in FIG. 5 includes a PMOSFET which is a specific example of a P-type FET and an NMOSFET which is a specific example of an N-type FET. The semiconductor device in FIG. 5 includes a CMOSFET which is constituted by the PMOSFET and the NMOSFET.

The semiconductor device shown in FIG. 5 includes a substrate 101, gate dielectric films 102, a gate electrode 103 for the PMOSFET, and a gate electrode 104 for the NMOSFET. The substrate 101 is a semiconductor substrate, all or a part of which is made of a semiconductor. The substrate 101 in this embodiment is a silicon substrate, all or a part of which is made of silicon. Each gate dielectric film 102 is a high-permittivity gate dielectric film, all or a part of which is made of a high-permittivity dielectric film. Each gate dielectric film 102 in this embodiment includes two layers of dielectric films: a first dielectric film 102A which is a silicon oxide film and a second dielectric film 102B which is a high-permittivity dielectric film. The gate electrode 103 for the PMOSFET is a metal gate electrode, all or a part of which is made of conductive metal. The gate electrode 103 for the PMOSFET in this embodiment includes three electrode-constituting layers: a first conductive layer 103A which is made of conductive metal, a second conductive layer 103B which is made of conductive metal, and a semiconductor layer 103C which is made of semiconductor. The gate electrode 104 for the NMOSFET is a metal gate electrode, all or a part of which is made of conductive metal. The gate electrode 104 for the NMOSFET in this embodiment includes one electrode-constituting layer: a third conductive layer 104A which is made of conductive metal.

Additionally, the semiconductor device shown in FIG. 5 has, as diffusion layers for the PMOSFET, a well diffusion layer 111 for the PMOSFET, a source/drain diffusion layer 112 for the PMOSFET, and an extension diffusion layer 113 for the PMOSFET.

Additionally, the semiconductor device shown in FIG. 5 has, as diffusion layers for the NMOSFET, a well diffusion layer 121 for the NMOSFET, a source/drain diffusion layer 122 for the NMOSFET, and an extension diffusion layer 123 for the NMOSFET.

Additionally, the semiconductor device shown in FIG. 5 has an isolation layer 131 for intervening between the source/drain diffusion layer 112 for the PMOSFET and the source/drain diffusion layer 122 for the NMOSFET, and an inter layer dielectric film 132 for intervening between the PMOSFET and the NMOSFET. The isolation layer 131 in this embodiment is an STI layer which is made of a silicon oxide film, and the inter layer dielectric film 132 in this embodiment is a silicon oxide film.

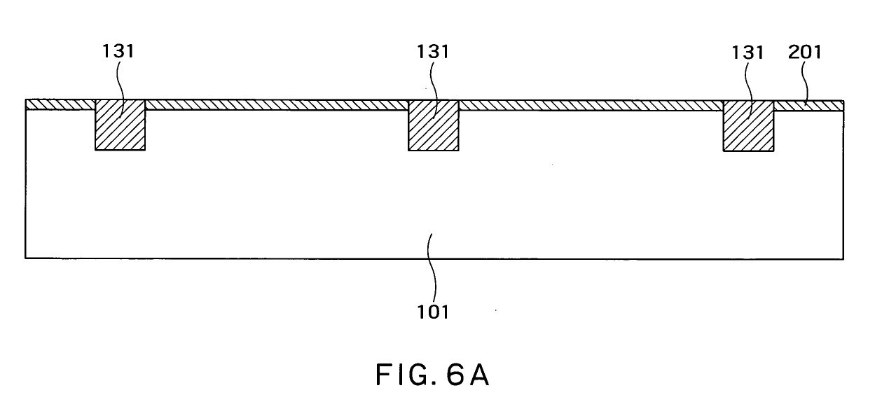

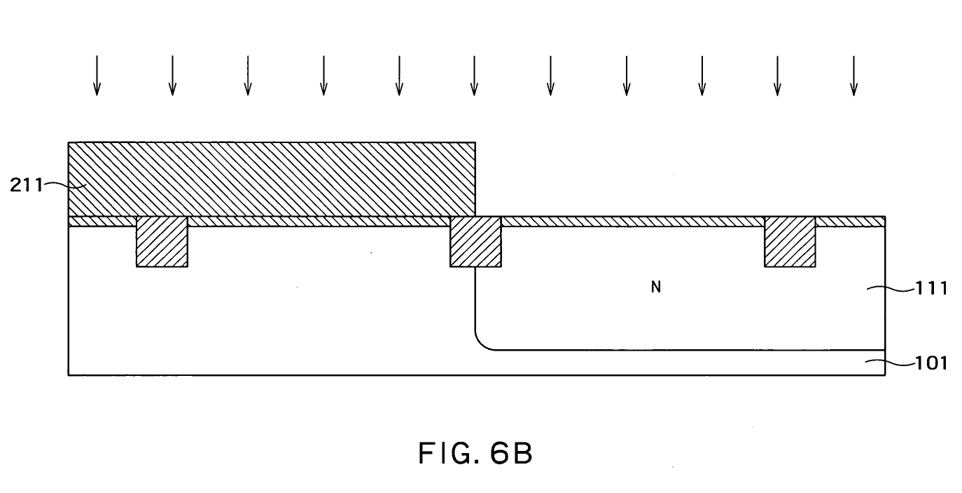

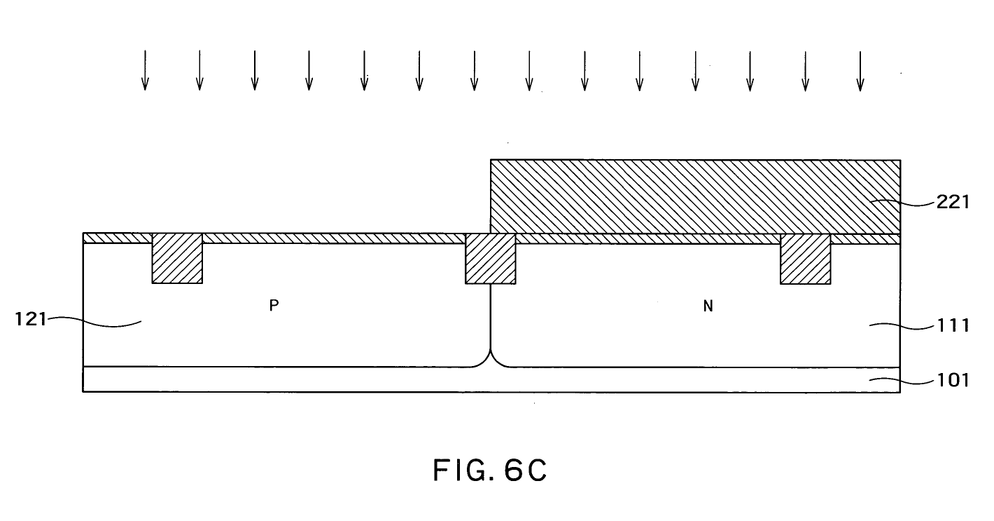

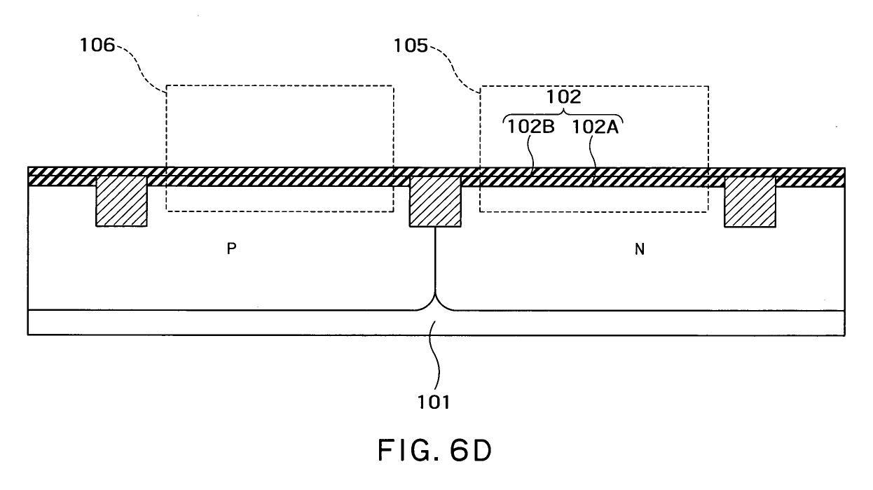

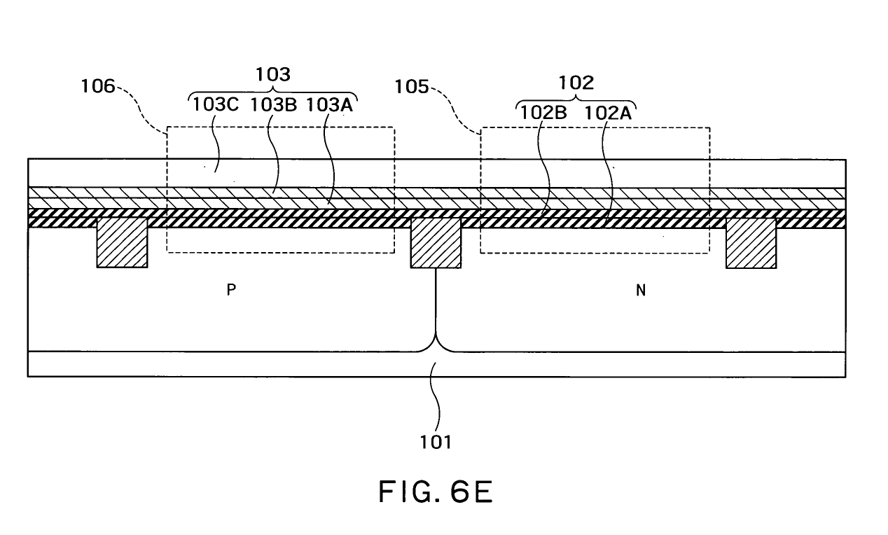

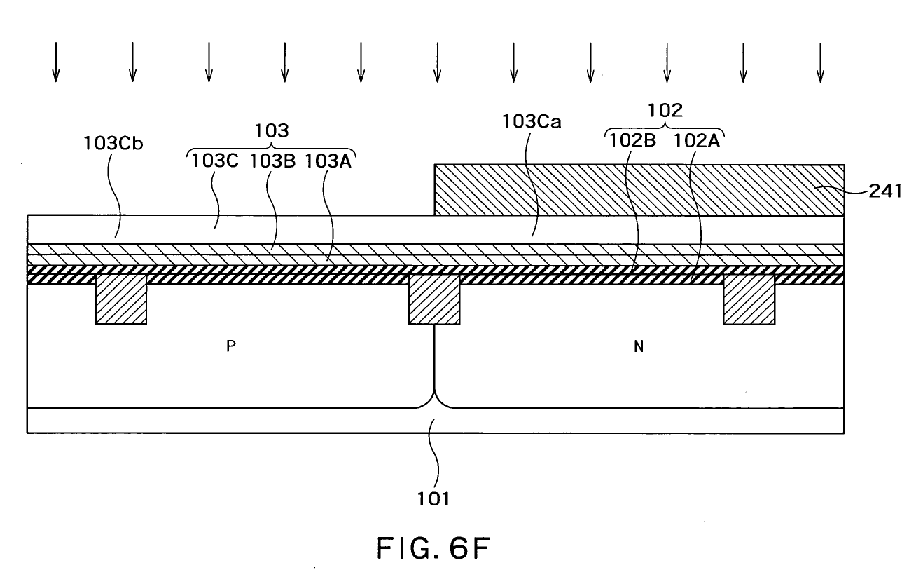

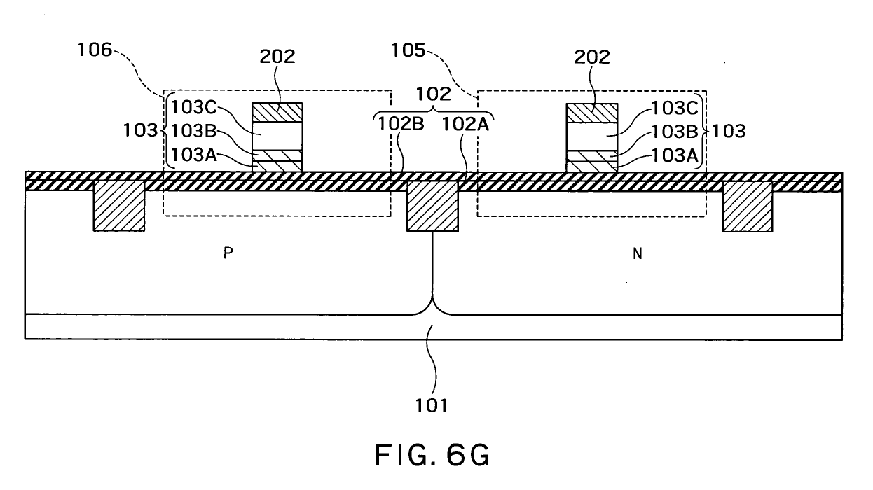

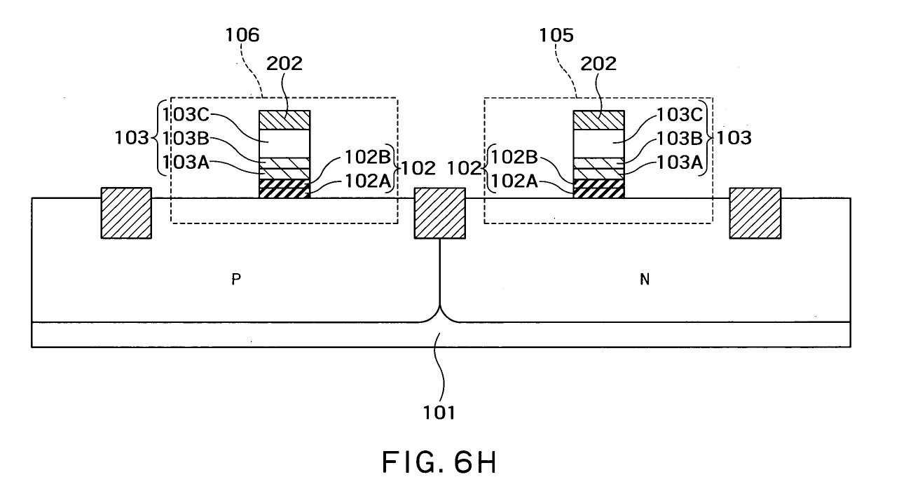

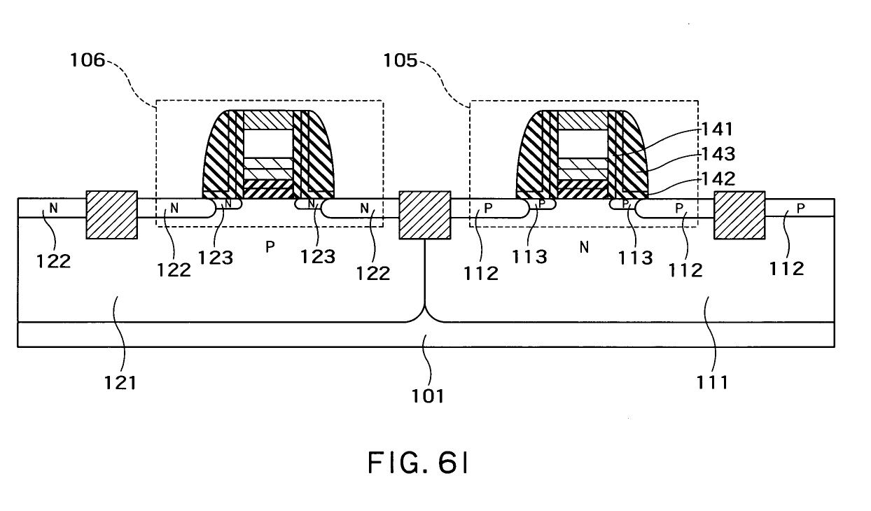

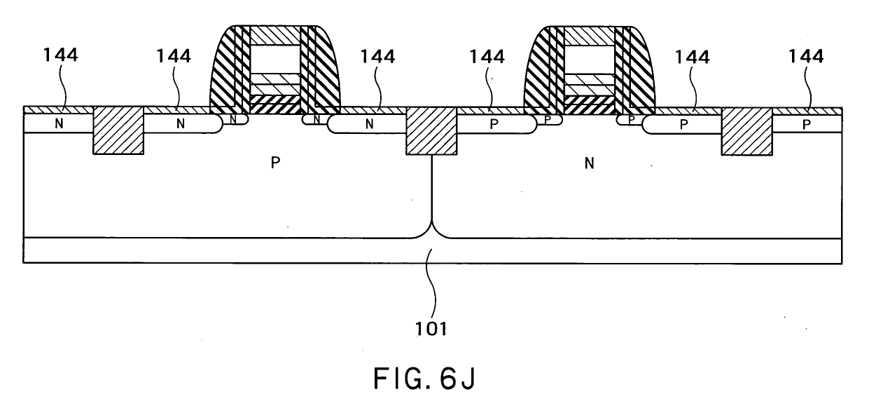

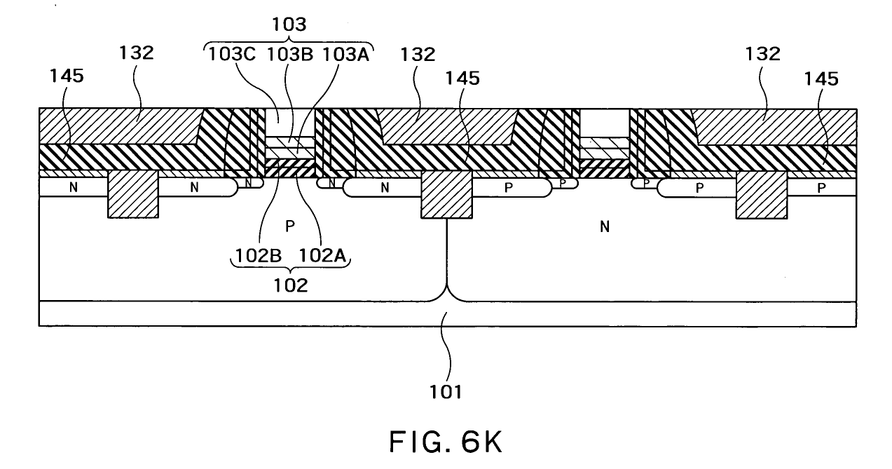

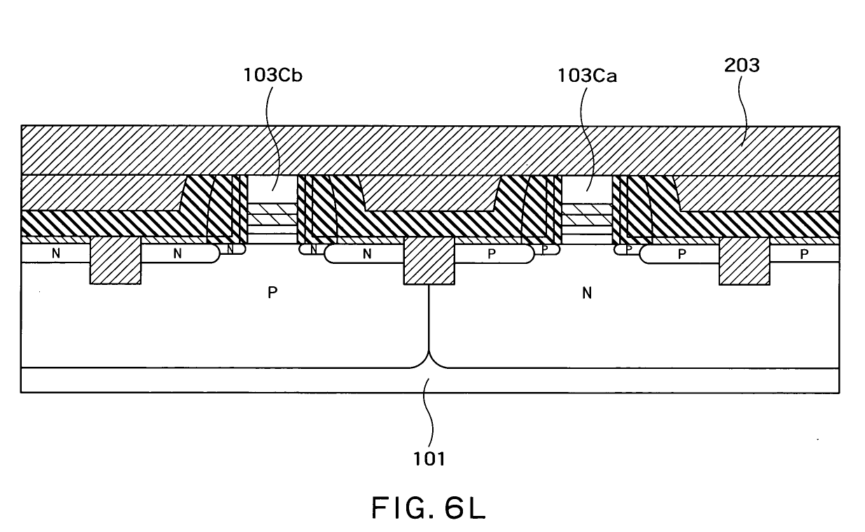

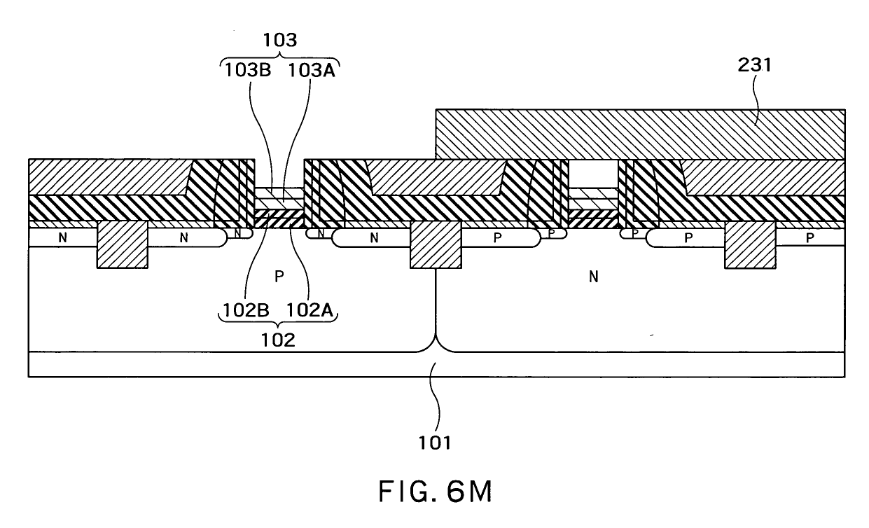

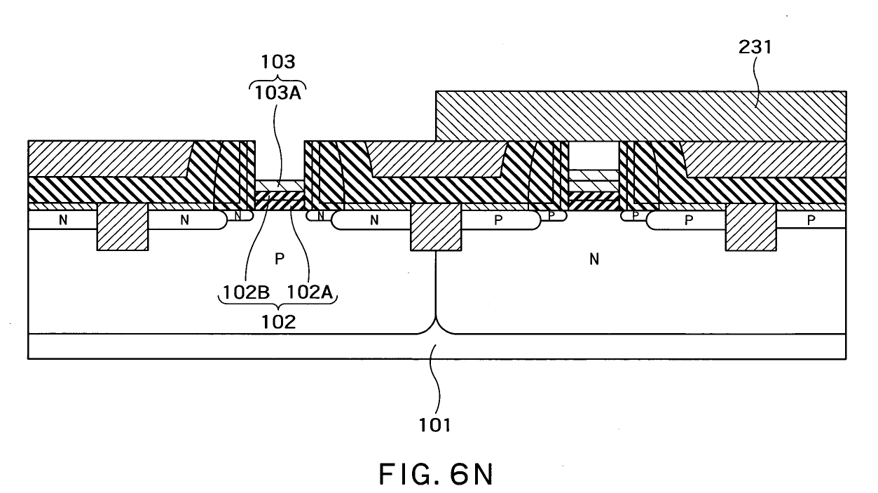

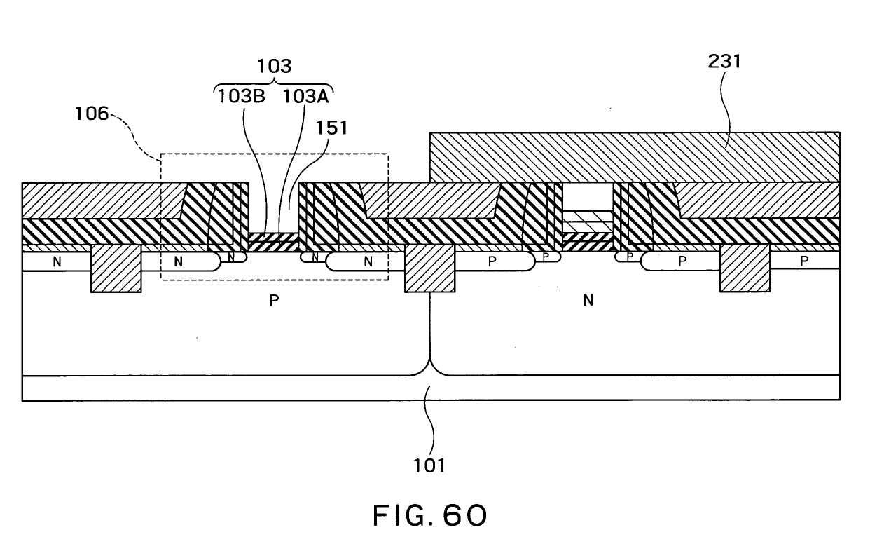

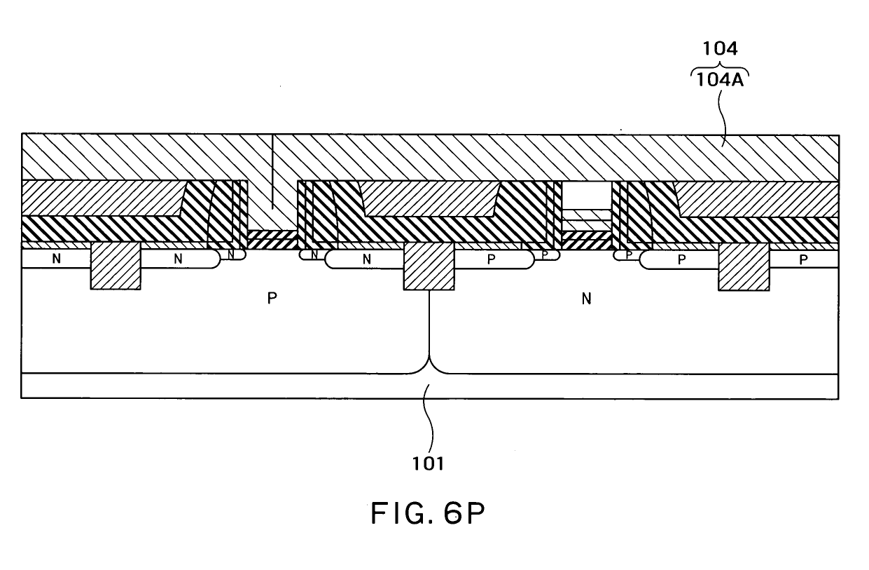

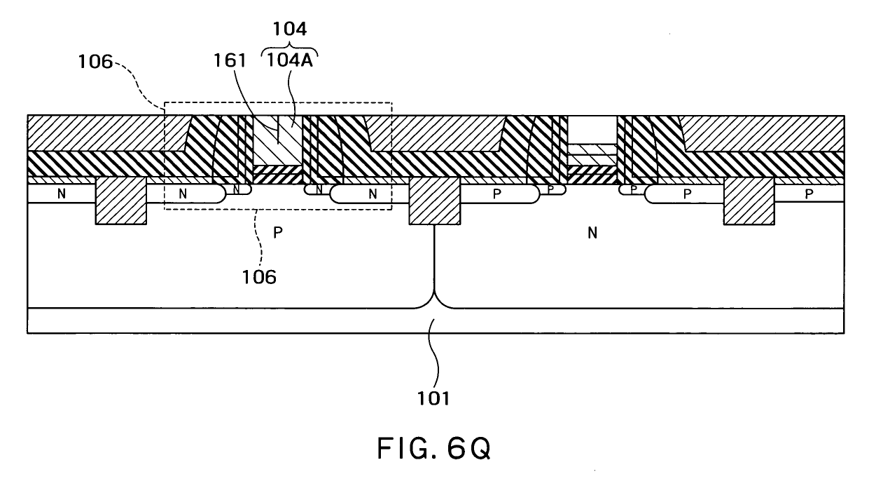

FIGS. 6A to 6Q are side sectional views showing a method for manufacturing the semiconductor device of the third embodiment.

First, as shown in FIG. 6A, silicon oxide films are buried in predetermined regions of a silicon substrate 101 to form isolation layers 131 of STIs. Then, as shown in FIG. 6A, a silicon oxide film (dielectric film) 201 is formed on the silicon substrate 101.

Next, as shown in FIG. 6B, ions of P (phosphorus) are implanted into the substrate 101 using a resist 211 as a mask.

Next, as shown in FIG. 6C, ions of B (boron) are implanted into the substrate 101 using a resist 221 as a mask. After that, the substrate 101 is subjected to thermal diffusion processing, thereby completing a well diffusion layer 111 for the PMOSFET and a well diffusion layer 121 for the NMOSFET.

Next, as shown in FIG. 6D, the dielectric film 201 is removed from the substrate 101 using an ammonium fluoride aqueous solution, and the surface of the substrate 101 is cleaned using 0.5 to 5.0% hydrofluoric acid. Then, as shown in FIG. 6D, a silicon oxide film (a first dielectric film of a gate dielectric film) 102A with a thickness of 0.5 to 0.8 nm is formed on the substrate 101 in an atmosphere containing oxygen, and a hafnium silicate film (a second dielectric film of the gate dielectric film) 102B with a thickness of about 2.0 nm is formed on the silicon oxide film 102A using tetrakis(diethylamino)hafnium, tetrakis(dimethylamino)silicon, and oxygen. After that, the substrate 101 is subjected to annealing at 600° C., thereby densifying the silicon oxide film 102A and hafnium silicate film 102B. After that, the substrate 101 is processed in a nitrogen plasma atmosphere or ammonia atmosphere and then subjected to annealing at 1,000° C., thereby reforming the hafnium silicate film 102B into a hafnium silicon oxynitride film 102B. With the above-described manufacturing steps, the gate dielectric film 102 common to the PMOSFET and NMOSFET is formed, ranging from a PMOSFET region 105 to a NMOSFET region 106, on the substrate 101. The PMOSFET region 105 is a region where the PMOSFET is to be formed, which is a specific example of a P-type FET region, and the NMOSFET region 106 is a region where the NMOSFET is to be formed, which is a specific example of an N-type FET region.

Next, as shown in FIG. 6E, a W (tungsten) layer (a first conductive layer of a gate electrode for the PMOSFET) 103A with a thickness of about 20 nm is deposited on the hafnium silicon oxynitride film 102B by thermal CVD using tungsten hexacarbonyl or plasma CVD using tungsten hexacarbonyl and hydrogen, a TiN (titanium nitride) layer (a second conductive layer of the gate electrode for the PMOSFET) 103B with a thickness of about 60 nm is deposited on the W layer 103A using diethylaminotitanium and ammonia, and a semiconductor layer 103C made of polysilicon or amorphous silicon is deposited on the TiN (titanium nitride) layer 103B. With the above-described manufacturing steps, the gate electrode 103 for the PMOSFET is formed, ranging from the PMOSFET region 105 to the NMOSFET region 106, on the gate dielectric film 102.

Next, as shown in FIG. 6F, ions of P or As are implanted into the semiconductor layer 103C above the well diffusion layer 121 for the NMOSFET, using a resist 241 above the well diffusion layer 111 for the PMOSFET as a mask. After that, the substrate 101 is subjected to thermal diffusion processing, thereby completing an N-type diffusion layer inside the semiconductor layer 103C. The inside of a part of the semiconductor layer 103C above the well diffusion layer 111 for the PMOSFET becomes a non-diffusion layer 103Ca, and the inside of a part of the semiconductor layer 103C above the well diffusion layer 121 for the NMOSFET becomes a diffusion layer 103Cb.

Next, as shown in FIG. 6G, the W layer 103A, TiN layer 103B, and semiconductor layer 103C (non-diffusion layer 103Ca and diffusion layer 103Cb) are processed using a dielectric film 202 as a hard mask, the dielectric film 202 including a silicon oxide film or silicon nitride film. With the above-described manufacturing steps, in the PMOSFET region 105 and the NMOSFET region 106, a gate electrode 103 for the PMOSFET is formed in the PMOSFET region 105, and a dummy gate electrode (a gate electrode used as a dummy) 103 with the same configuration as that of the gate electrode 103 for the PMOSFET is formed in the NMOSFET region 106.

Next, as shown in FIG. 6H, the silicon oxide film 102A and hafnium silicon oxynitride film 102B are processed using the dielectric film 202 as a hard mask. With the above-described manufacturing steps, in the PMOSFET region 105 and the NMOSFET region 106, a gate dielectric film 102 for the PMOSFET is formed in the PMOSFET region 105, and a gate dielectric film 102 for the NMOSFET is formed in the NMOSFET region 106. Gate dielectric films 102 for the PMOSFET and the NMOSFET are formed from the gate dielectric film 102 common to the PMOSFET and the NMOSFET.

Next, an offset spacer 141 made of a silicon oxide film or silicon nitride film and a side wall spacer 142 made of a silicon oxide film, are formed on the lateral surface of each gate electrode and gate dielectric film by CVD and RIE. Then, ions of B are implanted into the well diffusion layer 111 for the PMOSFET, ions of P or As are implanted into the well diffusion layer 121 for the NMOSFET, and the substrate 101 is subjected to annealing at 1,000° C.; with this process, the source/drain diffusion layer 112 for the PMOSFET and the source/drain diffusion layer 122 for the NMOSFET are formed, as shown in FIG. 6I. Also, ions of B are implanted into the well diffusion layer 111 for the PMOSFET, ions of P or As are implanted into the well diffusion layer 121 for the NMOSFET, and the substrate 101 is subjected to annealing at 1,000° C.; with this process, the extension diffusion layer 113 for the PMOSFET and the extension diffusion layer 123 for the NMOSFET are formed, as shown in FIG. 6I. Then, side wall spacers 143, each of which is made of a silicon nitride film, are formed by CVD and RIE. With the above-described manufacturing steps, in the PMOSFET region 105 and NMOSFET region 106, the source/drain diffusion layer 112 and extension diffusion layer 113 for the PMOSFET and the source/drain diffusion layer 122 and extension diffusion layer 123 for the NMOSFET are formed in the substrate 101.

Next, as shown in FIG. 6J, silicide films 144 are formed in a self-aligned manner on the surfaces of the source/drain diffusion layer 112 for the PMOSFET and the source/drain diffusion layer 122 for the NMOSFET.

Next, as shown in FIG. 6K, an etch stopper film 145 made of a silicon nitride film is formed over the entire surface by CVD. Then, as shown in FIG. 6K, an inter layer dielectric film 132 made of a silicon oxide film is formed over the entire surface. Then, as shown in FIG. 6K, the surface of the substrate 101 is planarized by chemical mechanical polishing or etching (dry etching or wet etching). With the above-described manufacturing steps, the semiconductor layers 103C (non-diffusion layers 103Ca and diffusion layers 103Cb) are exposed both in the PMOSFET region 105 and the NMOSFET region 106.

Next, as shown in FIG. 6L, a Ni (nickel) film (sacrificial film) 203 is formed over the entire surface. After that, the substrate 101 is subjected to annealing, thereby siliciding Ni in the Ni film 203. At this time, since the diffusion layer 103Cb contains P or As, the silicidation rate of the diffusion layer 103Cb becomes higher than that of the non-diffusion layer 103Ca. Accordingly, Ni monosilicide (NiSi) is formed in the non-diffusion layer 103Ca, and a Ni-rich silicide (Ni₂Si, Ni₃Si, or the like) is formed in the diffusion layer 103Cb.

Next, as shown in FIG. 6M, in the NMOSFET region 106, the semiconductor layer 103C above the gate dielectric film 102 for the NMOSFET is etched using a resist 231 as a mask and using a chemical solution such as a solution containing hydrogen peroxide. With the above-described manufacturing steps, the TiN layer 103B in the NMOSFET region 106 is exposed.

Next, as shown in FIG. 6N, in the NMOSFET region 106, the TiN layer 103B above the gate dielectric film 102 for the NMOSFET is etched using the resist 231 as a mask and using a chemical solution such as a solution containing hydrogen peroxide. With the above-described manufacturing step, the W layer 103A in the NMOSFET region 106 is exposed.

Next, as shown in FIG. 6O, in the NMOSFET region 106, the W layer 103A on the gate dielectric film 102 for the NMOSFET is etched using the resist 231 as a mask and using a chemical solution such as a solution containing hydrogen peroxide. With the above-described manufacturing step, the hafnium silicon oxynitride film 102B in the NMOSFET region 106 is exposed. Through the above-described manufacturing steps, in the NMOSFET region 106, the dummy gate electrode 103 on the gate dielectric film 102 is removed, thereby forming a trench 151 on the gate dielectric film 102.

Next, as shown in FIG. 6P, conductive metal, which is a material for forming a third conductive layer 104A of the gate electrode 104 for the NMOSFET, is formed over the entire surface by CVD. Examples of the conductive metal include TaCN, which is formed using tris-dimethylamino-mono-t-amyliminotantalum and monomethylamine.

Next, as shown in FIG. 6Q, the surface of the substrate 101 is planarized by chemical mechanical polishing or etching (etchback). Through the above-described manufacturing steps, in the NMOSFET region 106, the material for forming the gate electrode is buried in the trench 151 on the gate dielectric film 102, thereby forming the gate electrode 104 for the NMOSFET with a different configuration from that of the gate electrode 103 for the PMOSFET. Since the gate electrode 104 for the NMOSFET (the third conductive layer 104A) is formed in the hole by CVD, a trace of a streaky seam 161 which does not remain in the gate electrode 103 for the PMOSFET (the first conductive layer 103A, second conductive layer 103B, and semiconductor layer 103C) remains in the gate electrode 104 for the NMOSFET.

After that, the substrate 101 is subjected to steps of forming a wiring layer, an inter layer dielectric film between wiring layers, a contact hole, a via hole, a plug layer, and the like as appropriate, and the semiconductor device is finally completed.

In the third embodiment, the gate electrode 103 for the PMOSFET includes the first conductive layer 103A made of the conductive metal, the second conductive layer 103B made of the conductive metal, and the semiconductor layer (silicide layer) 103C made of the semiconductor (silicide). For this reason, in the third embodiment, the gate resistance of the PMOSFET is relatively low.

As described above, according to the embodiments of the present invention, it is possible to provide a semiconductor device including a P-type FET and an N-type FET which are constituted by gate dielectric films and gate electrodes with preferable characteristics.

What is claimed is:

1. A manufacturing method of a semiconductor device, for forming a P-type FET and an N-type FET in a P-type FET region and an N-type FET region of a substrate respectively, the method comprising:
forming a gate dielectric film common to the P-type FET and the N-type FET, ranging from the P-type FET region to the N-type FET region, on the substrate;
forming a gate electrode layer for the P-type FET, ranging from the P-type FET region to the N-type FET region, on the gate dielectric film;
processing, in the P-type FET region and the N-type FET region, the gate electrode layer for the P-type FET, to form a gate electrode for the P-type FET in the P-type FET region, and to form a dummy gate electrode in the N-type FET region;
forming, in the P-type FET region and the N-type FET region, a source/drain diffusion layer for the P-type FET and a source/drain diffusion layer for the N-type FET in the substrate, after the gate electrode for the P-type FET and the dummy gate electrode are formed;
forming, in the N-type FET region, a trench on the gate dielectric film, by removing the dummy gate electrode on the gate dielectric film; and
forming, in the N-type FET region, a gate electrode for the N-type FET on the gate dielectric film, by burying a gate electrode material in the trench on the gate dielectric film.

2. The method according to claim 1, wherein:
in forming the gate electrode layer for the P-type FET,
a first conductive layer which is a layer constituting the gate electrode layer for the P-type FET, is formed on the gate dielectric film, and
a second conductive layer which is a layer constituting the gate electrode layer for the P-type FET, is formed on the first conductive layer; and
in forming the gate electrode for the N-type FET,
a third conductive layer which is a layer constituting the gate electrode for the N-type FETE is formed on the gate dielectric film.

3. The method according to claim 1, wherein:
in forming the gate electrode layer for the P-type FET,
a first conductive layer which is a layer constituting the gate electrode layer for the P-type FET, is formed on the gate dielectric film,
a second conductive layer which is a layer constituting the gate electrode layer for the P-type FET, is formed on the first conductive layer, and
a semiconductor layer which is a layer constituting the gate electrode layer for the P-type FET, is formed on the second conductive layer; and
in forming the gate electrode for the N-type FET,
a third conductive layer which is a layer constituting the gate electrode for the N-type FET, is formed on the gate dielectric film.

4. The method according to claim 1, wherein:
in forming the gate dielectric film,
a first dielectric film which is a dielectric film constituting the gate dielectric film, is formed on the substrate, and
a second dielectric film which is a dielectric film constituting the gate dielectric film, is formed on the first dielectric film.

5. The method according to claim 2, wherein each of the first, second, and third conductive layers is formed of conductive metal.

6. The method according to claim 2, wherein the first conductive layer is formed of conductive metal capable of being removed without a chemical solution.

7. The method according to claim 2, wherein the first conductive layer is formed of conductive metal capable of being removed using a chemical solution.

8. The method according to claim 2, wherein the first conductive layer is formed of Ru (ruthenium).

9. The method according to claim 2, wherein the first conductive layer is formed of W (tungsten).

10. The method according to claim 4, wherein the second dielectric film is formed of a high-permittivity dielectric film.

11. The method according to claim 1, wherein all or a part of the gate dielectric film is formed of a high-permittivity dielectric film.

12. The method according to claim 1, wherein all or a part of the gate electrode layer for the P-type FET is formed of conductive metal.

13. The method according to claim 1, wherein all or a part of the gate electrode for the N-type FET is formed of conductive metal.

14. The method according to claim 1, wherein all or a part of the gate electrode layer for the P-type FET is formed of conductive metal capable of being removed without a chemical solution.

15. The method according to claim 1, wherein all or a part of the gate electrode layer for the P-type FET is formed of conductive metal capable of being removed using a chemical solution.

16. The method according to claim 1, wherein all or a part of the gate electrode layer for the P-type FET is formed of Ru (ruthenium).

17. The method according to claim 1, wherein all or a part of the gate electrode layer for the P-type FET is formed of W (tungsten).

18. The method according to claim 1, wherein:
no seam is formed in the gate electrode for the P-type FET; and
a seam is formed in the gate electrode for the N-type FET.

19. A semiconductor device comprising:
a substrate;
a gate dielectric film for a P-type FET and a gate dielectric film for an N-type FET, formed on the substrate and formed from a gate dielectric film common to the P-type FET and the N-type FET;
a gate electrode for the P-type FET, formed on the gate dielectric film for the P-type FET and having no seam in the gate electrode; and
a gate electrode for the N-type FET, formed on the gate dielectric film for the N-type FET and having a seam in the gate electrode.

20. A semiconductor device manufactured by forming a P-type FET and an N-type FET in a P-type FET region and an N-type FET region of a substrate respectively, the device being manufactured by:
forming a gate dielectric film common to the P-type FET and the N-type FET, ranging from the P-type FET region to the N-type FET region, on the substrate;
forming a gate electrode layer for the P-type FET, ranging from the P-type FET region to the N-type FET region, on the gate dielectric film;
processing, in the P-type FET region and the N-type FET region, the gate electrode layer for the P-type FET, to form a gate electrode for the P-type FET in the P-type FET region, and to form a dummy gate electrode in the N-type FET region;
forming, in the P-type FET region and the N-type FET region, a source/drain diffusion layer for the P-type FET and a source/drain diffusion layer for the N-type FET in the substrate, after the gate electrode for the P-type FET and the dummy gate electrode are formed;
forming, in the N-type FET region, a trench on the gate dielectric film, by removing the dummy gate electrode on the gate dielectric film; and
forming, in the N-type FET region, a gate electrode for the N-type FET on the gate dielectric film, by burying a gate electrode material in the trench on the gate dielectric film.
